(19) United States
(12) Patent Application Publication
(10) Pub. No.: US 2014/0213068 A1
(43) Pub. Date: Jul. 31, 2014

(54) FILM DEPOSITION APPARATUS AND FILM DEPOSITION METHOD

(71) Applicant: Tokyo Electron Limited, Tokyo (JP)

(72) Inventors: Hitoshi Kato, Iwate (JP); Manabu Honma, Iwate (JP); Yasushi Takeuchi, Iwate (JP)

(73) Assignee: Tokyo Electron Limited, Tokyo (JP)

(21) Appl. No.: 14/243,977

(22) Filed: Apr. 3, 2014

Related U.S. Application Data
(63) Continuation of application No. 12/969,757, filed on Dec. 16, 2010.

(30) Foreign Application Priority Data
Dec. 25, 2009 (JP) 2009-295391

(51) Int. Cl. H01L 21/02; H01L 21/677

(52) U.S. Cl. CPC H01L 21/0228; H01L 21/67706
USPC 438/765; 118/704

(57) ABSTRACT

A film deposition apparatus includes a separation member that extends to cover a rotation center of the turntable and two different points on a circumference of the turntable above the turntable, thereby separating the inside of the chamber into a first area and a second area; a first reaction gas supplying portion that supplies a first reaction gas toward the turntable in the first area; a second reaction gas supplying portion that supplies a second reaction gas toward the turntable in the second area; a first evacuation port that evacuates the first reaction gas and the first separation gas that converges with the first reaction gas; and a second evacuation port that evacuates the second reaction gas and the first separation gas that converges with the second reaction gas. The separation member has a bent portion that substantially fills in a gap between the turntable and the chamber.

### CROSS-REFERENCE TO RELATED APPLICATION

This application is a continuation application of U.S. patent application Ser. No. 12/969,757 filed on Dec. 16, 2010. This application is based on and claims the benefit of priority of Japanese Patent Application No. 2009-295391, filed on Dec. 25, 2009 with the Japanese Patent Office, the entire contents of which are hereby incorporated by reference.

### BACKGROUND OF THE INVENTION

1. Field of the Invention

The present invention relates to a film deposition apparatus and a film deposition method for depositing a film on a substrate by carrying out plural cycles of supplying in turn at least two source gases to the substrate in order to form a layer of a reaction product.

2. Description of the Related Art

As a film deposition method in a semiconductor fabrication process, there has been known a so-called Atomic Layer Deposition (ALD) or Molecular Layer Deposition (MLD). In the ALD method, plural cycles are repeated that includes a first reaction gas adsorption step where a first reaction gas is supplied to a vacuum chamber in order to allow the first reaction gas to be adsorbed on a surface of a semiconductor wafer (referred to as a wafer hereinafter), a first purge step where the first reaction gas is purged from the vacuum chamber using a purge gas, a second reaction gas adsorption step where a second reaction gas is supplied to a vacuum chamber in order to allow the second reaction gas to be adsorbed on the surface of the wafer, and a second purge step where the second reaction gas is purged from the vacuum chamber using the purge gas, thereby depositing a film through reaction of the first and the second reaction gases on the surface of the wafer. This method is advantageous in that the film thickness can be controlled at higher accuracy by the number of cycles of alternately supplying the gases, and in that the deposited film can have excellent uniformity over the wafer. Therefore, this deposition method is thought to be promising as a film deposition technique that can address further miniaturization of semiconductor devices.

As a film deposition apparatus for carrying out such a film deposition method, Patent Document 1 discloses a film evaporation apparatus provided with a rotatable susceptor that has a disk shape and provided in a reaction chamber and a gas supplying portion arranged to oppose the susceptor. The gas supplying portion includes one circular center showerhead arranged in an upper center area of the reaction chamber and ten sector-shaped showerheads arranged to surround the center showerhead. One of the ten showerheads supplies a first source gas; another one of the ten showerheads that is located symmetrically in relation to the showerhead supplying the first source gas with respect to the center circular showerhead supplies a second source gas; and the remaining sector showerheads and the circular center showerhead supply a purge gas. In addition, plural evacuation openings are arranged along an inner surface of the reaction chamber, and thus the gases supplied from the showerheads flow in outward radial directions and are evacuated from the plural evacuation openings. While reducing intermixture of the first source gas and the second source gas in the reaction chamber in such a manner, the source gases are substantially switched by rotating the susceptor, thereby eliminating the need of the purge steps.

In addition, Patent Document 2 below discloses a film deposition apparatus provided with a substrate supporting platform that is rotatable and vertically movable in a reaction chamber and supports four substrates thereon, and four reaction spaces defined above the substrate supporting platform. In this film deposition apparatus, the substrate supporting platform is rotated until the substrates thereon can be positioned below the corresponding reaction spaces, stopped and moved upward in order to expose the substrates to the corresponding reaction spaces. Then, one reaction gas is supplied in a predetermined period of time (in pulse) to at least one of the reaction spaces, and the other reaction gas is supplied in a predetermined period of time (in pulse) to another one of the reaction spaces. Next, the reaction spaces to which the corresponding reaction gases are supplied are purged with a purge gas. While the purge gas is being supplied, the substrate supporting platform is moved downward and then rotated until the substrates are positioned below the subsequent reaction spaces. In the following, the substrate supporting platform is moved upward and the same operations are repeated. Namely, the reaction gases and the purge gas are supplied in a time-divisional manner, and do not flow at the same time. In addition, when the substrate is exposed to the reaction space to which the reaction gas is supplied, the substrate supporting platform is sealed by a member extending from the ceiling member of the reaction chamber, so that the substrate rather than the substrate supporting platform is exposed to the reaction gas. With this, no film deposition takes place on the substrate supporting platform, thereby reducing particle generation.
Patent Document 1: Korean Patent Application Laid-Open Publication No. 10-2009-0012396.
Patent Document 2: United States Patent Application Publication No. 2007/0215036.

### SUMMARY OF THE INVENTION

In the film deposition apparatus disclosed in Patent Document 1, even if the reaction gases are made to flow in outward radial directions by providing plural evacuation openings along the inner circumferential wall of the reaction chamber, because the gases are likely to flow in a rotation direction of the susceptor when the susceptor is rotated, especially at higher speeds, the intermixture of the first source gas and the second source gas is not sufficiently suppressed. When the intermixture takes place, an appropriate ALD cannot be realized. Because of such a circumstance, a rotation speed of 3 revolutions per minute (rpm) through 10 rpm is exemplified in Patent Document 1. Such a low rotation speed is not acceptable from a viewpoint of production throughput.

In addition, in the film deposition method disclosed in Patent Document 2, it takes a relatively long time to purge the reaction space. Moreover, because cycles of the substrate supporting platform being rotated, stopped, moved upward, and moved downward are repeated and the reaction gases are intermittently supplied, it is difficult to increase production throughput.

The present invention has been made in view of the above, and provides a film deposition apparatus and a film deposition method that are capable of impeding intermixture of a first reaction gas and a second reaction gas even when a rotation speed of a turntable is increased, thereby improving throughput.

According to a first aspect of the present invention, there is provided a film deposition apparatus for depositing a film on a substrate by performing plural cycles of alternately supplying at least two kinds of reaction gases that react with each other on the substrate to produce a layer of a reaction product in a chamber. The film deposition apparatus includes a turntable that is rotatably provided in a chamber and includes a substrate receiving area in which a substrate is placed; a separation member that extends to cover a rotation center of the turntable and two different points on a circumference of the turntable above the turntable, thereby separating the inside of the chamber into a first area and a second area, wherein a pressure in a space between the turntable and the separation member may be maintained higher than pressures of the first area and the second area by use of a first separation gas supplied to the space; a pressure control portion that maintains along with the separation member the pressure in the space between the turntable and the separation member higher than the pressures in the first area and the second area; a first reaction gas supplying portion that is provided in the first area and supplies a first reaction gas toward the turntable; a second reaction gas supplying portion that is provided in the second area and supplies a second reaction gas toward the turntable; a first evacuation port that evacuates therefrom the first reaction gas supplied in the first area and the first separation gas supplied to the space between the separation member and the turntable by way of the first area, after the first reaction gas and the first separation gas converge with each other in the first area; and a second evacuation port that evacuates therefrom the second reaction gas supplied in the second area and the first separation gas supplied to the space between the separation member and the turntable by way of the second area, after the second reaction gas and the first separation gas converge with each other in the second area.

According to a second aspect of the present invention, there is provided a film deposition method for depositing a film on a substrate by carrying out plural cycles of alternately supplying at least two kinds of reaction gases that react with each other on the substrate to produce a layer of a reaction product in a chamber. The film deposition method includes steps of placing a substrate in a substrate receiving area of a turntable that is rotatably provided in the chamber; supplying a first separation gas to a space between the turntable and a separation member that extends to cover a rotation center of the turntable and two different points on a circumference of the turntable above the turntable, thereby separating the inside of the chamber into a first area and a second area, so that a pressure in the space is greater than pressures of the first area and the second area; supplying a first reaction gas from a first gas supplying portion arranged in the first area toward the turntable; supplying a second reaction gas from a second gas supplying portion arranged in the second area toward the turntable; evacuating the first reaction gas supplied to the first area and the first separation gas from the space between the turntable and the separation member by way of the first area, after the first reaction gas and the first separation gas converge in the first area; and evacuating the second reaction gas supplied to the second area and the first separation gas from the space between the turntable and the separation member by way of the second area, after the second reaction gas and the first separation gas converge in the second area.

### BRIEF DESCRIPTION OF THE DRAWINGS

FIG. 1 is a cross-sectional view of a film deposition apparatus according to an embodiment of the present invention;

FIG. 2 is a perspective view schematically illustrating the inside of a vacuum chamber of the film deposition apparatus of FIG. 1;

FIG. 3 is a plan view of the vacuum chamber of the film deposition apparatus of FIG. 1;

FIG. 4 has cross-sectional views illustrating an example of a separation area, a first area, and a second area in the vacuum chamber of the film deposition apparatus of FIG. 1;

FIG. 5 is another cross-sectional view of the vacuum chamber of the film deposition apparatus of FIG. 1;

FIG. 6 has explanatory views for explaining a size of a separation area in the vacuum chamber of the film deposition apparatus of FIG. 1;

FIG. 7 illustrates results of computer simulation carried out on the pressure in the separation area in the vacuum chamber of the film deposition apparatus of FIG. 1;

FIG. 8 is a schematic view of a pressure distribution in the separation area in the vacuum chamber of the film deposition apparatus of FIG. 1;

FIG. 9 is another cross-sectional view of the vacuum chamber of the film deposition apparatus of FIG. 1;

FIG. 10 is a partial broken perspective view illustrating the vacuum chamber of the film deposition apparatus of FIG. 1;

FIG. 11 is a schematic view of a reaction gas nozzle and a nozzle cover attached to the reaction gas nozzle in the vacuum chamber of the film deposition apparatus of FIG. 1;

FIG. 12 is an explanatory view of the reaction gas nozzle with the nozzle cover of FIG. 11;

FIG. 13 is an explanatory view illustrating a gas flow pattern in the vacuum chamber of the film deposition apparatus of FIG. 1;

FIG. 14 is another cross-sectional view of the vacuum chamber of the film deposition apparatus of FIG. 1;

FIG. 15 is yet another cross-sectional view of the vacuum chamber of the film deposition apparatus of FIG. 1;

FIG. 16 is a plan view illustrating a flow regulatory plate to be used in the vacuum chamber of the film deposition apparatus of FIG. 1;

FIG. 17 is a cross-sectional view of the flow regulatory plate of FIG. 16;

FIG. 18 illustrates results of computer simulations carried out on the pressure in the separation area in the vacuum chamber of the film deposition apparatus of FIG. 1, comparing pressure differences according to evacuation ports;

FIG. 19 illustrates a modified example of the reaction gas nozzle and a separation gas nozzle in the vacuum chamber of the film deposition apparatus of FIG. 1;

FIG. 20 illustrates another modified example of the reaction gas nozzle and a separation gas nozzle in the vacuum chamber of the film deposition apparatus of FIG. 1;

FIG. 21A illustrates a modified example of the separation area in modified example of the reaction gas nozzle and a separation gas nozzle in the vacuum chamber of the film deposition apparatus of FIG. 1;

FIG. 21B is a cross-sectional view taken along an E-E line in FIG. 21A;

FIG. 22 illustrates another modified example of the separation area;

FIG. 23 illustrates another modified example of the separation area;

FIG. 24 illustrates another modified example of the separation area;

FIG. 25 illustrates another modified example of the separation area;

FIG. 26 illustrates another modified example of the separation area;

FIG. 27 illustrates another modified example of the separation area;

FIG. 28 illustrates a modified example of the nozzle cover of FIG. 11;

FIG. 29 illustrates another modified example of the nozzle cover;

FIG. 30 illustrates another modified example of the nozzle cover;

FIG. 31 is a cross-sectional view of a film deposition apparatus according to another embodiment of the present invention; and

FIG. 32 is a schematic view of a wafer processing apparatus including a film deposition apparatus according to an embodiment of the present invention.

### DETAILED DESCRIPTION OF THE PREFERRED EMBODIMENT

According to an embodiment of the present invention, there are provided a film deposition apparatus and a film deposition method that are capable of impeding intermixture of a first reaction gas and a second reaction gas even when a rotation speed of a turntable is increased, thereby improving throughput.

Non-limiting, exemplary embodiments of the present invention will now be described with reference to the accompanying drawings. In the drawings, the same or corresponding reference symbols are given to the same or corresponding members or components. It is noted that the drawings are illustrative of the invention, and there is no intention to indicate scale or relative proportions among the members or components. Therefore, the specific thicknesses or sizes should be determined by a person having ordinary skill in the art in view of the following non-limiting embodiments.

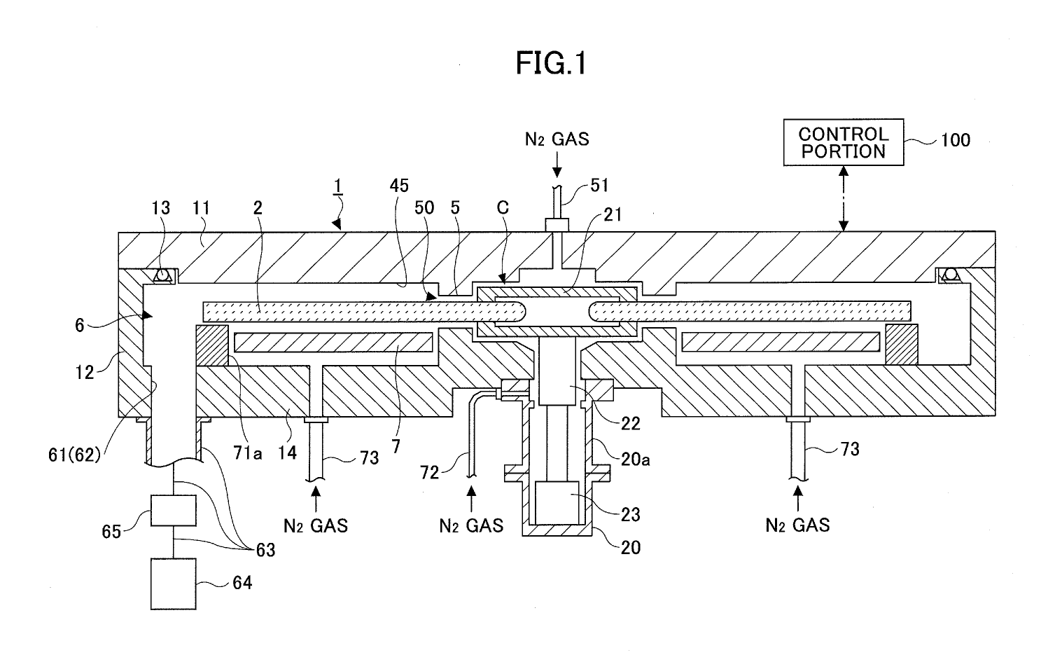

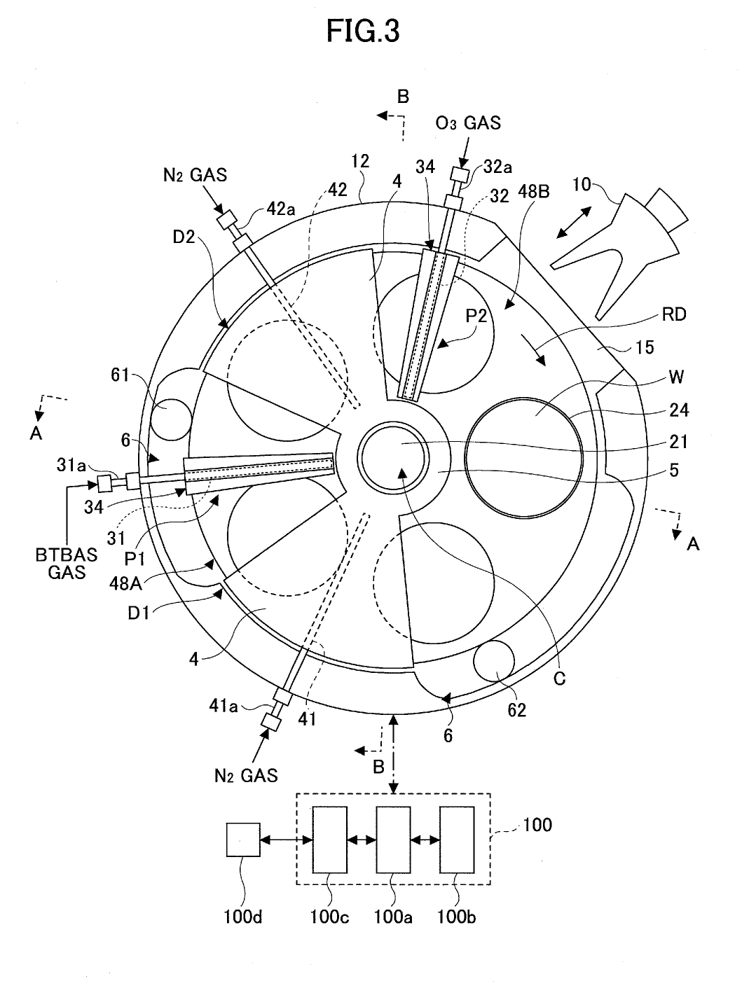

Referring to FIG. 1, which is a cut-away diagram taken along A-A line in FIG. 3, a film deposition apparatus according to an embodiment of the present invention is provided with a flattened cylinder shape whose top view is substantially circular, and a turntable 2 that is located inside the chamber 1 and has a rotation center at a center of the vacuum chamber 1. The vacuum chamber 1 is made so that a ceiling plate 11 can be separated from a chamber body 12. The ceiling plate 11 is attached onto the chamber body 12 via a sealing member 13 such as an O-ring, so that the vacuum chamber 1 is sealed in an air-tight manner. On the other hand, the ceiling plate 11 can be raised by a driving mechanism (not shown) when the ceiling plate 11 has to be removed from the chamber body 12. The ceiling plate 11 and the chamber body 12 may be made of, for example, aluminum (Al).

Referring to FIG. 1, the turntable 2 has a circular opening in the center and is supported in such a manner that a portion around the opening of the turntable 2 is held from above and below by a core portion 21 having a cylindrical shape. The core portion 21 is fixed on a top end of a rotational shaft 22 that extends in a vertical direction. The rotational shaft 22 goes through a bottom portion 14 of the chamber body 12, and is fixed at the lower end to a driving mechanism 23 that can rotate the rotational shaft 22 around a vertical axis. With these configurations, the turntable 2 can be rotated around its center. The rotational shaft 22 and the driving mechanism 23 are housed in a case body 20 having a cylinder with a bottom. The case body 20 is fixed in an air-tight manner to a bottom surface of the bottom portion 14 via a flanged pipe portion 20a, so that an inner environment of the case body 20 is isolated from an outer environment.

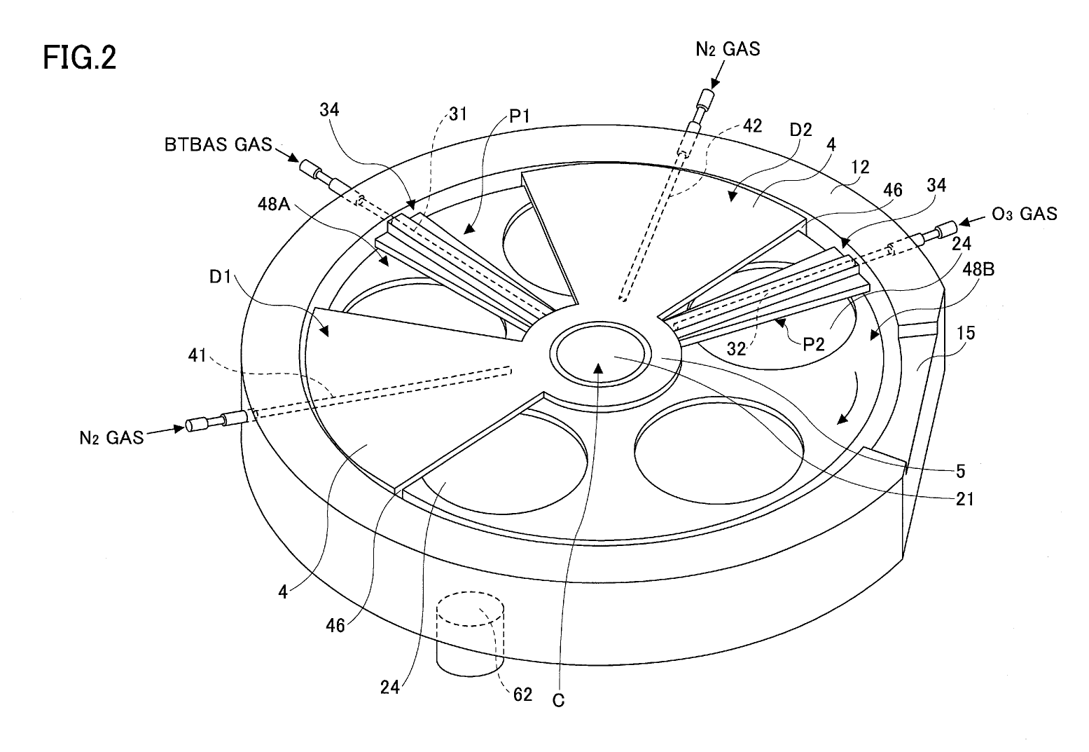

As shown in FIGS. 2 and 3, plural (five in the illustrated example) circular-shaped concave portions 24, each of which receives a wafer W, are formed at equal angular intervals in the upper surface of the turntable 2, although only one wafer W is illustrated in FIG. 3, for convenience of illustration.

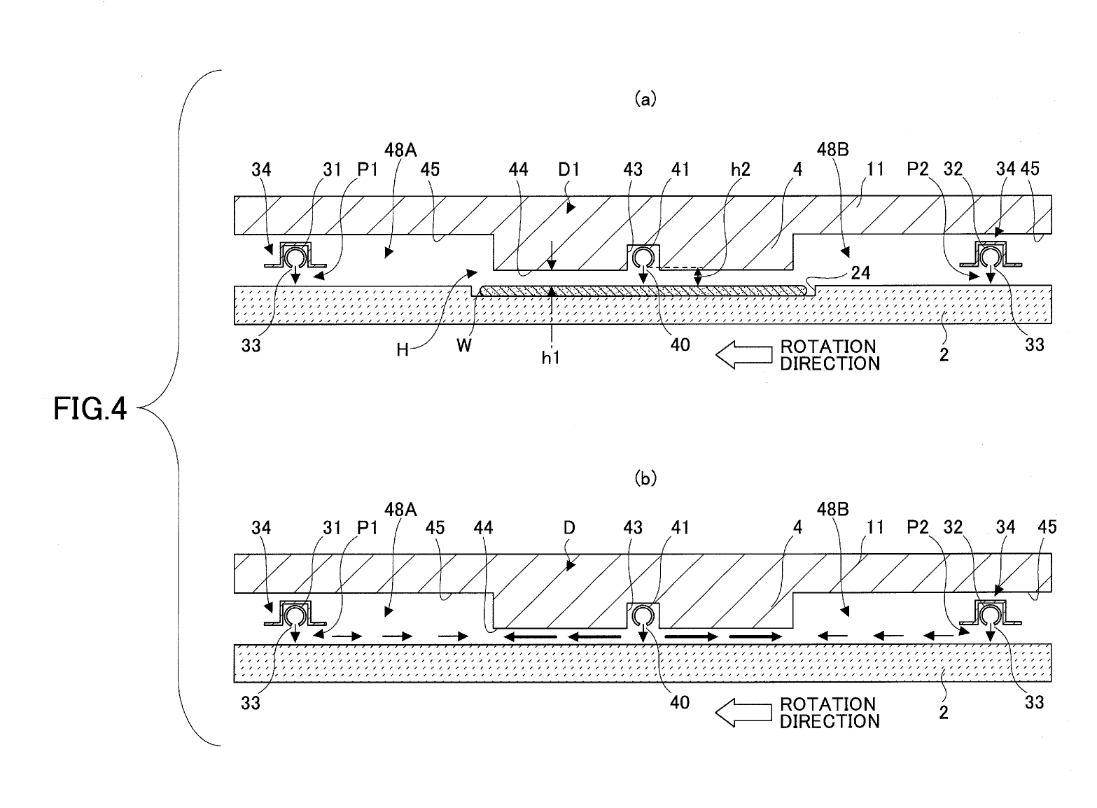

Referring to Section (a) of FIG. 4, which is a cross-sectional view illustrating the concave portion 24, the concave portion 24 has a diameter slightly larger, for example, by 4 mm than the diameter of the wafer W and a depth substantially equal to a thickness of the wafer W. Because of the depth substantially equal to the wafer thickness, when the wafer W is placed in the concave portion 24, a surface of the wafer W is at the same elevation of a surface of an area of the turntable 2, the area excluding the concave portions 24. If there is a relatively large step between the area and the wafer W, gas flow turbulence is caused by the step, which adversely influences across-wafer uniformity of a film thickness. It is preferable in order to reduce such influence that the surfaces of the wafer W and the turntable 2 are at the same elevation. While “the same elevation” may mean here that a height difference is less than or equal to about 5 mm, the difference has to be as close to zero as possible to the extent allowed by machining accuracy.

Referring to FIGS. 2 through 4, two convex portions 4 are provided that are arranged in a rotation direction (see an arrow RD in FIG. 3) and away from each other. Although, the ceiling plate 11 is omitted in FIGS. 2 and 3, the convex portions 4 are attached on a lower surface of the ceiling plate 11. As shown in FIG. 3, each of the convex portions 4 has a top view shape of a truncated sector whose apex is severed along an arc line. The inner (or top) arc is coupled with a protrusion portion 5 (described later) and an outer (or bottom) arc lies near and along the inner circumferential wall of the chamber body 12. In addition, the convex portion 4 is designed and arranged so that the lower surface of the convex portion 4 is located at a height h1 from the turntable 2. With this, there is a space H between the convex portion 4 and the turntable 2.

Referring to Sections (a) and (b) of FIG. 4, the convex portion 4 has a groove portion 43 that extends in the radial direction and substantially bisects the convex portion 4. Separation gas nozzles 41, 42 are located in the groove portions 43 of the corresponding convex portions 4. Incidentally, while the groove portion 43 is formed in order to bisect the convex portion 4 in this embodiment, the groove portion 43 is formed so that an upstream side of the convex portion 4 relative to the rotation direction of the turntable 2 is wider, in other embodiments. The separation gas nozzles 41, 42 are introduced from the outer circumference wall of the chamber body 12 and supported by attaching their base ends, which are gas inlet ports 41a, 42a, respectively.

The separation gas nozzles 41, 42 are connected to separation gas sources (not shown) that supply a separation gas. The separation gas is preferably inert gas such as N₂ gas and noble gas, but may be various gases as long as the separation gas does not adversely influence the film deposition. In this embodiment, N₂ gas is used as the separation gas. The separation gas nozzles 41, 42 have plural ejection holes (see FIG. 4) to eject the separation gases downward from the plural ejection holes 40. The plural ejection holes 40 are arranged at predetermined intervals in longitudinal directions of the separation gas nozzles 41, 42. The ejection holes 40 have an inner diameter of about 0.5 mm, and are arranged at intervals of about 10 mm in this embodiment. In other embodiments, the separation gas nozzles 41, 42 may have slits that extend in the longitudinal direction and open toward the turntable 2.

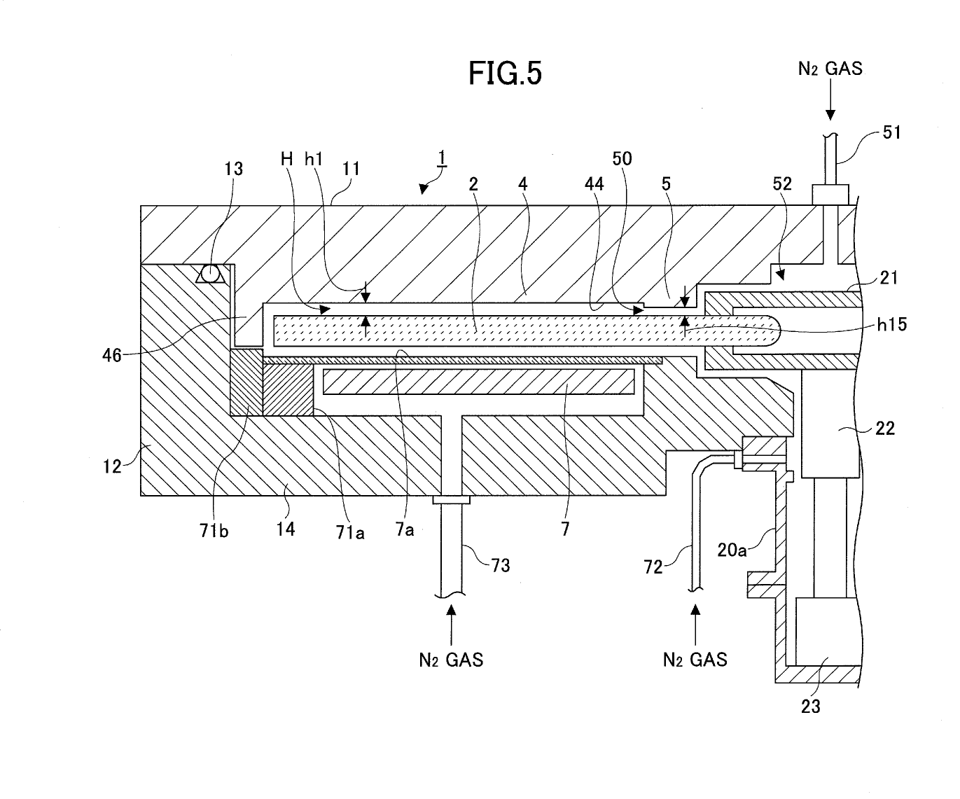

Referring again to FIGS. 1 through 3, a ring-shaped protrusion portion 5 is provided on a back surface of the ceiling plate 11 in order to surround the core portion 21. As stated, the inner arc of the convex portion 4 is coupled with the protrusion portion 5. With this configuration, a separation member is provided that separates the inner space into a first area 48A and a second area 48B (FIGS. 2 and 3). The protrusion portion 5 opposes the turntable 2, thereby creating a thin space 50 with respect to the turntable 2. The thin space 50 is in pressure communication with the space H created between the convex portion 4 and the turntable 2. In this embodiment, a height h15 (see FIG. 5) of the lower surface of the protrusion portion 5 (the thin space 50) from the turntable 2 is slightly lower than the height h1 of the space H. In other embodiments, the height H15 may be equal to the height H1. Incidentally, the convex portions 4 may be integrally formed with the protrusion portion 5, or separately formed and coupled. It is noted that FIGS. 2 and 3 illustrate the inside of the vacuum chamber whose top plate 11 is removed while the convex portions 4 remain inside the chamber 1.

FIG. 5 shows a half portion of a cross-sectional view of the chamber 1, taken along a B-B line in FIG. 3. As shown in the drawing, a space 52 is created between the ceiling plate 11 of the vacuum chamber 1 and the core portion 21. The space 52 is in pressure communication with the space 50, and thus the spaces H below the corresponding two convex portions are in pressure communication with each other through the spaces 50 and 52. In addition, a separation gas supplying pipe 51 is connected to a center portion of the ceiling plate 11, and separation gas (e.g., N₂) is supplied to the space 52 between the ceiling plate 11 and the core portion 12 through the separation gas supplying pipe 51.

Referring to FIGS. 2 and 3, a reaction gas nozzle 31 is introduced from the circumferential wall of the chamber body 12 in the radius direction of the turntable 2 in the first area 48A, and a reaction gas nozzle 32 is introduced from the circumferential wall of the chamber body 12 in the radius direction of the turntable 2 in the first area 48B. These reaction gas nozzles 31, 32 are supported by attaching base portions, which are gas introduction ports 31a, 32a, respectively, in the same manner as the separation gas nozzles 41, 42. Incidentally, the reaction gas nozzles 31, 32 may be arranged at a predetermined angle with respect to the radius direction of the turntable 2 in other embodiments. The first area 48A and the second area 48B have a high ceiling surface 45 (the lower surface of the ceiling plate 11) higher than the low ceiling surface 45 (the lower surface of the convex portions 4).

Although not shown, the reaction gas nozzle 31 is connected to a first gas supplying source of a first reaction gas and the reaction gas nozzle 32 is connected to a gas supplying source of a second reaction gas. While various combinations of gases including those described later as the first reaction gas and the second gas may be used, bis (tertiary-butylamino) silane (BTBAS) gas is used as the first reaction gas and O₃ (ozone) gas is used as the second reaction gas. Incidentally, an area below the reaction gas nozzle 31 may be referred to as a first process area P1 in which the BTBAS gas is adsorbed on the wafer W, and an area below the reaction gas nozzle 32 may be referred to as a second process area P2 in which the BTBAS gas adsorbed on the wafer W is oxidized by the O₃ gas, in the following explanation.

In addition, the reaction gas nozzles 31, 32 have plural ejection holes 33 (see FIG. 4) in order to eject the corresponding reaction gases toward the upper surface of the turntable 2 (or the surface where the concave portions 24 are formed). The plural ejection holes 33 are arranged in longitudinal directions of the reaction gas nozzles 31, 32 at predetermined intervals. The ejection holes 33 have an inner diameter of about 0.5 mm, and are arranged at intervals of about 10 mm in this embodiment. In other embodiments, the reaction gas nozzles 31, 32 may have slits that extend in the longitudinal direction and open toward the turntable 2. As shown in FIG. 3, the reaction gas nozzles 31, 32 are provided with corresponding nozzle covers 34, which are explained later.

In the above configuration, when the N₂ gas is ejected from the separation gas nozzle 41 (or 42), the N₂ gas reaches the space H between the convex portion 4 and the turntable 2, and the pressure of the space H can be maintained higher than those of the first and the second areas 48A, 48B. In addition, when the N₂ gas is supplied from the separation gas supplying nozzle 41 to the space 52, the N₂ gas reaches from the space 52 to the space 50 between the protrusion portion 5 and the turntable 2, and thus the pressure of the space 50 can be maintained higher than those of the first and the second areas 48A, 48B. In such a manner, a separation space is created that includes the space 50 between the protrusion portion 5 and the turntable, the space 52 between the core portion and the ceiling plate 11, and the spaces H between the two convex portions 4 and the turntable 2, the spaces H being in pressure communication with the spaces 50 and 52, thereby separating the first and the second areas 48A, 48B. Incidentally, an area corresponding to the convex portion 4 located upstream relative to the rotation direction of the turntable 2 in relation to the first area 48A may be called a separation area D1; an area corresponding to the convex portion 4 located downstream relative to the rotation direction of the turntable 2 in relation to the first area 48A may be called a separation area D2; and a circular area corresponding to the protrusion portion 5 may be called a center separation area C (see FIGS. 2 and 3), for convenience of explanation in the following.

In order to confirm that the higher pressure can be maintained at the separation space below the convex portions 4 and the protrusion portion 5 compared to the first and the second areas 48A, 48B, computer simulation was carried out, under the following conditions.

flow rates of the N₂ gases from each of the separation gas nozzles 41, 42: 12,500 standard cubic centimeters per minute (sccm)

flow rate of the N₂ gas from the separation gas supplying nozzle 51: 5,000 sccm

rotation speed of the turntable 2: 240 revolutions per minute (rpm)

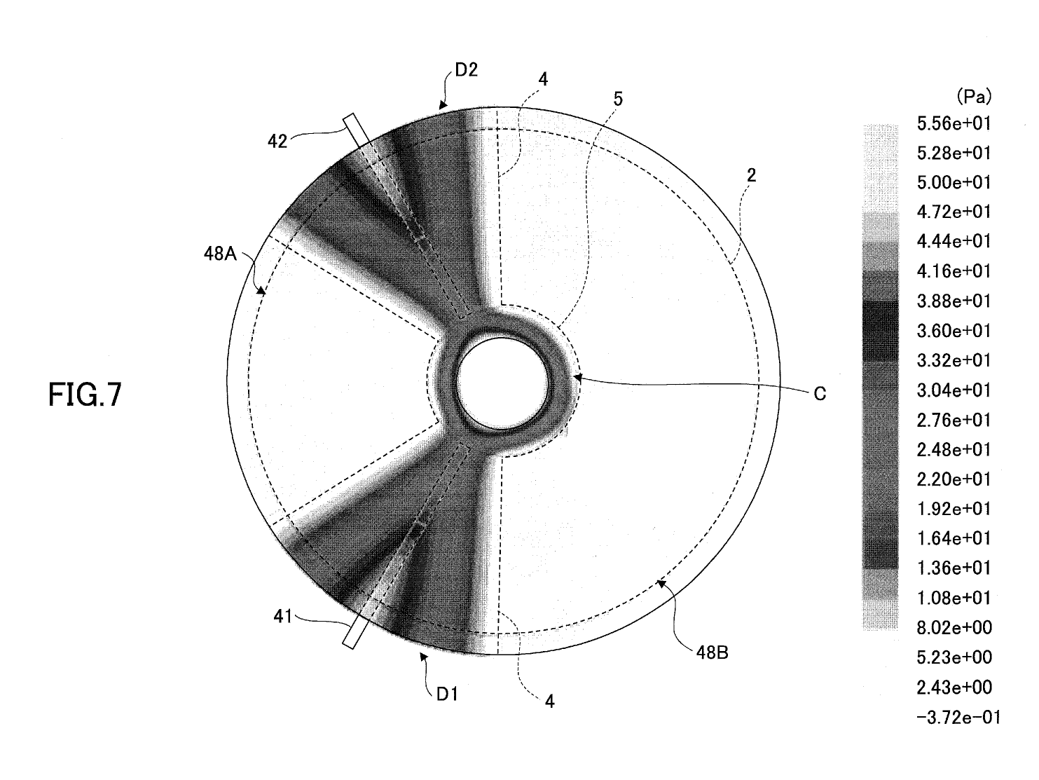

As shown in FIG. 7, the pressure of the separation areas D1, D2 and the center separation area C is maintained higher by the N₂ gas supplied from the separation gas nozzles 41, 42 and the separation gas supplying nozzle 51 than those of the first and the second areas 48A, 48B. In addition, the pressure in, for example, the separation area D1 becomes higher toward the center of the separation area D1 along the circumferential direction of the turntable 2. Specifically, the highest pressure is observed in a region below the separation gas nozzle 41 and near the circumference of the turntable 2. Incidentally, a high pressure region (e.g., 52.8 Pa) and a low pressure region (e.g., 5.23 Pa) are indicated by the same white color in FIG. 7, because of a black-and-white presentation. However, the pressure is distributed as explained above.

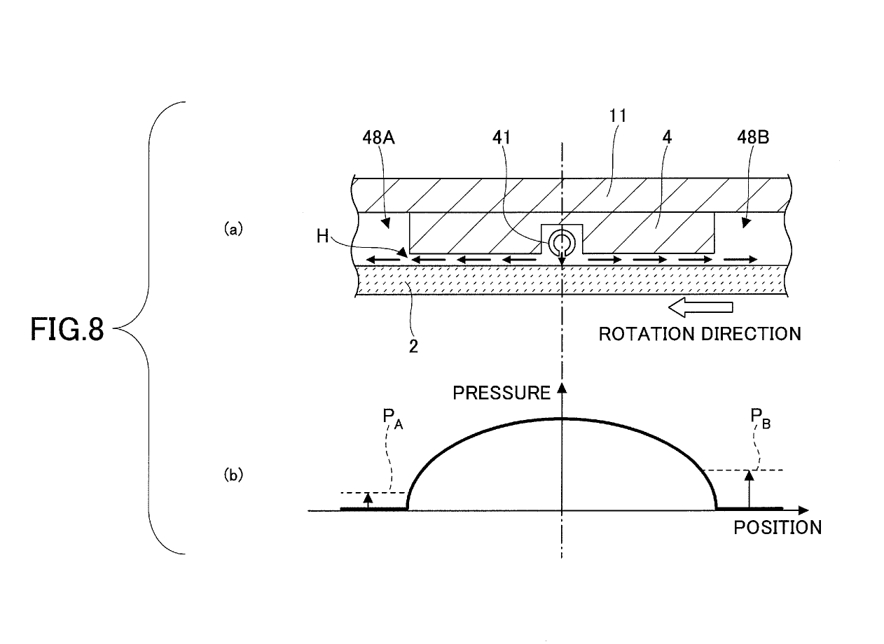

In addition, as schematically shown in Section (a) of FIG. 8, the pressure in the space H of the separation area D1 is the highest below the separation gas supplying nozzle 41 and becomes lower toward the first and the second areas 48A, 48B. For example, as shown in Section (b) of FIG. 8, even when the pressure of the first area 48A is increased to PA by supplying the BTBAS gas and the pressure of the second area 48B is increased to PB by supplying O₃ gas, the pressures PA, PB can be maintained lower than the pressure of the space H. Therefore, the BTBAS gas cannot flow over the pressure barrier thereby to reach the second area 48B and the O₃ gas cannot flow over the pressure barrier thereby to reach the first area 48A. Namely, the BTBAS gas and the O₃ gas are substantially prevented from being intermixed with each other in gas phase.

In addition, because the pressures of the spaces H of the separation areas D1, D2 and the space 50 of the center separation area C are higher than the those of the first and the second areas 48A, 48B, the N₂ gas supplied to the areas D1, D2, and C flows outward to the first and the second areas 48A, 48B. In other words, the convex portions 4 and the protrusion portion 5 guide the N₂ gas supplied from the separation gas nozzles 41, 42 and the separation gas supplying portion 51 to the first and the second areas 48A, 48B from the separation areas D1, D2 and the center separation area C. In other words, the separation space (the spaces H, the space 50, and the space 52) is maintained at a higher pressure than the first and the second areas 48A, 48B, thereby providing a counter flow against the BTBAS gas and the O₃ gas as well as the pressure barrier. In such a manner, the BTBAS gas and the O₃ gas can be effectively separated, in this embodiment, even when the rotation speed is increased, thereby leading to increased production throughput.

Incidentally, because of the height differences between the low ceiling surfaces 44 (the lower surface of the convex portions 4) and the high ceiling surfaces 45 (the lower surface of the ceiling plate 11), volumes of the spaces H and the space 50 are smaller than those of the first and the second area 48A, 48B, which contributes to maintaining the pressure of the separation space higher than those of the first and the second areas 48A, 48B.

Next, the height h1 (see Section (a) of FIG. 4) of the low ceiling surface 44 from the upper surface of the turntable 2 is exemplified. The height h1 is determined so that the pressure of the space H can be maintained higher than those of the first and the second areas 48A, 48B, depending on the flow rate of the N₂ gas supplied from the separation gas nozzle 41 (or 42). For example, the height h1 is preferably 0.5 mm through 10 mm, and more preferable as small as possible. However, the height h1 may be, for example, 3.5 mm through 6.5 mm, taking into consideration concerns of the turntable 2 hitting the ceiling surface 44 because of vertical vibration that may be caused during rotation. On the other hand, the height h15 of the protrusion portion 5, which is located above a center portion of the turntable 2, from the turntable 2 may be lower than the height h1 because the vertical vibration of the turntable 2 is smaller in an inner portion of the turntable 2. Specifically, the height h15 is preferably 1.0 mm through 3.0 mm. Incidentally, a height h2 (see Section (a) of FIG. 4) of the lower end of the separation gas nozzle 41 (or 42), which is housed in the groove portion of the convex portion 4, may be, for example, at a range from 0.5 mm through 4 mm.

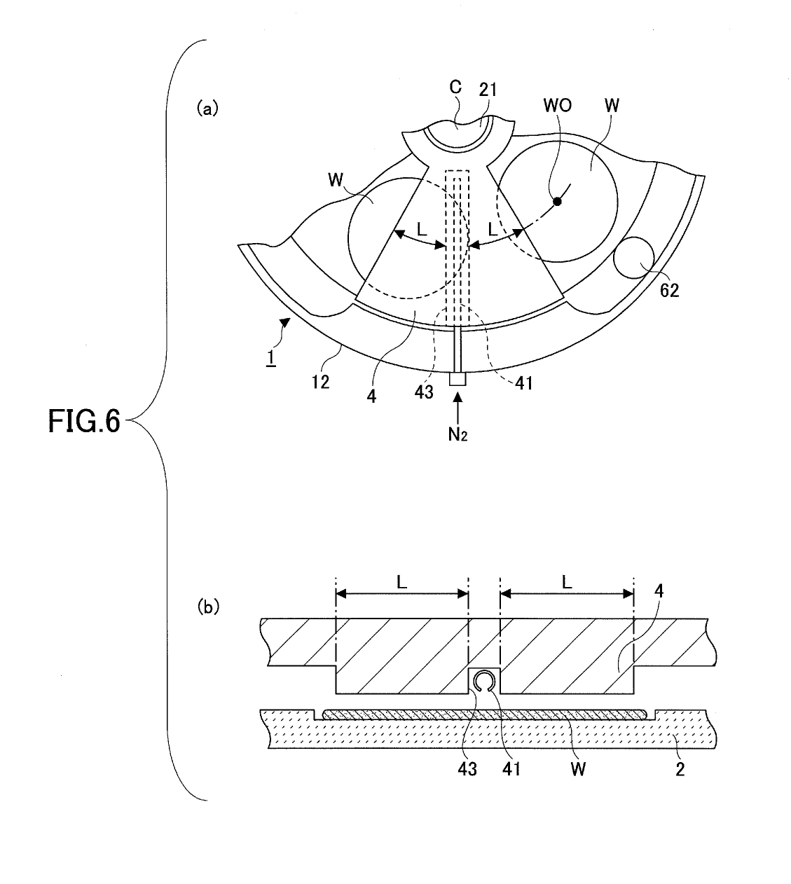

In addition, as shown in Sections (a) and (b) of FIG. 6, the convex portion 4 may preferably have a length L ranging from about one-tenth of a diameter of the wafer W through about a diameter of the wafer W, preferably, about one-sixth or more of the diameter of the wafer W along an arc that corresponds to a route through which a wafer center WO passes. When the convex portion 4 has such a size, the separation space can be better maintained at a higher pressure than the first and the second areas 48A, 48B. Incidentally, because the separation gas nozzle 41 (or 42) has an outer diameter of about 13 mm in this embodiment, a width of the groove portion 43 of the convex portion 43 may be from 13 mm through 15 mm. The length L is preferably determined taking into consideration the width of the groove portion 43.

In addition, because a larger centrifugal force is applied to the gases in the vacuum chamber 1 at a position closer to the outer circumference of the turntable 2, the BTBAS gas, for example, flows toward the separation area D at a higher speed in the position closer to the outer circumference of the turntable 2. Therefore, the BTBAS gas is more likely to flow into the space H between the ceiling surface 44 and the turntable 2 in the position closer to the circumference of the turntable 2. In view of this, it is preferable for the convex portion 4 to have a sector-shaped top view, as explained in this embodiment.

Referring again to FIG. 5, the convex portion 4 has a bent portion 46 that bends in an L-shape at the outer circumferential edge of the convex portion 4. The bent portion 46 substantially fills out a space between the turntable 2 and the chamber body 12. The gaps between the bent portion 46 and the turntable 2 and between the bent portion 46 and the chamber body 12 may be smaller than or equal to the height h1 of the ceiling surface 44 from the turntable 2. Incidentally, the gap between the turntable 2 and the chamber body 12 is preferably determined, taking into consideration thermal expansion of the turntable 2, so that the gap that is smaller than or equal to the height h1 of the low ceiling surface 44 is realized when the turntable 2 is heated to a predetermined film deposition temperature. With this configuration, the BTBAS gas supplied from the reaction gas nozzle 31 in the first area 48A is impeded from flowing into the second area 48B through the gap between the turntable 2 and the inner circumferential surface of the chamber body 12, and the O₃ gas supplied from the reaction gas nozzle 32 in the second area 48B is impeded from flowing into the first area 48A through the gap between the turntable 2 and the inner circumferential surface of the chamber body 12. In addition, because of the bent portion 46, the N₂ gas from the separation gas nozzle 41 (or 42) is less likely to flow toward the outer circumference of the turntable 2. Namely, the bent portion 46 contributes to maintaining the space H higher than the first and the second areas 48A, 48B. Incidentally, a block member 71b may be preferably provided between the turntable 2 and the inner circumferential wall of the chamber body 12, as shown in FIG. 5, so that the separation gas is impeded from flowing around and below the turntable 2.

On the other hand, the inner circumferential wall of the chamber body 12 is indented in the first and the second areas 48A, 48B, so that evacuation areas 6 are formed, as shown in FIGS. 3, 9, and 10. Evacuation ports 61, 62 are formed in bottoms of the corresponding evacuation areas 6. The evacuation ports 61, 62 are connected to a common vacuum pump 64 serving as an evacuation portion via corresponding evacuation pipes 63. With these configurations, the first and the second areas 48A, 48B are evacuated. Namely, such arrangement of the evacuation ports 61, 62 facilitates maintaining the pressure of the separation space higher than those of the first and the second areas 48A, 48B.

Referring again to FIG. 1, the evacuation pipe 63 is provided with a pressure controller 65. Plural pressure controllers 65 may be provided to the corresponding evacuation ports 61, 62. Incidentally, while the evacuation ports 61, 62 are formed in the bottoms of the evacuation areas 6 in this embodiment, the evacuation ports 61, 62 may be provided in the circumferential wall of the chamber body 12. In addition, the evacuation ports 61, 62 may be formed in the ceiling plate 11. However, in this case, because the gases flow upward to the evacuation ports 61, 62, particles may be blown upward by the gases. From this point of view, the evacuation ports 61, 62 are preferably formed in the bottoms of the evacuation areas 6 or the circumferential wall of the chamber body 12. In addition, when the evacuation ports 61, 62 are formed in the bottoms, the evacuation pipes 63, the pressure controller 65, and the vacuum pump 64 can be arranged below the vacuum chamber 1, which is advantageous in reducing a footprint of the film deposition apparatus.

As shown in FIGS. 1, 5, and 9, a ring-shaped heater unit 7 serving as a heating portion is provided in a space between the bottom portion 14 of the chamber body 12 and the turntable 2, so that the wafers W placed on the turntable 2 are heated through the turntable 2 at a determined temperature. In addition, a block member 71a is provided beneath the turntable 2 and near the outer circumference of the turntable 2 in order to surround the heater unit 7, so that the space where the heater unit 7 is placed is partitioned from the outside area of the block member 71a. The block member 71a is arranged in such a manner that a slight gap remains between an upper surface of the block member 71a and the lower surface of the turntable 2 in order to impede gas from flowing into the space where the heater unit 7 is arranged, from the outside area. In addition plural purge gas supplying pipes 73 are connected at predetermined angular intervals to the bottom portion 14 of the chamber body 12, in order to supply inert gas (e.g., N₂ gas) to the space where the heater unit 7 is housed. With this N₂ gas from the purge gas supplying pipes 73, the reaction gas is more effectively impeded from flowing into the space where the heater unit 7 is housed.

Incidentally, a protection plate 7a that protects the heater unit 7 is supported by the block member 71a and a raised portion R (described later) above the heater unit 7. With this, even if the gases such as the BTBAS gas or the O₃ gas flow around below the turntable 2, the heater unit 7 can be protected from those gases. The protection plate 7a is preferably made of, for example, quartz.

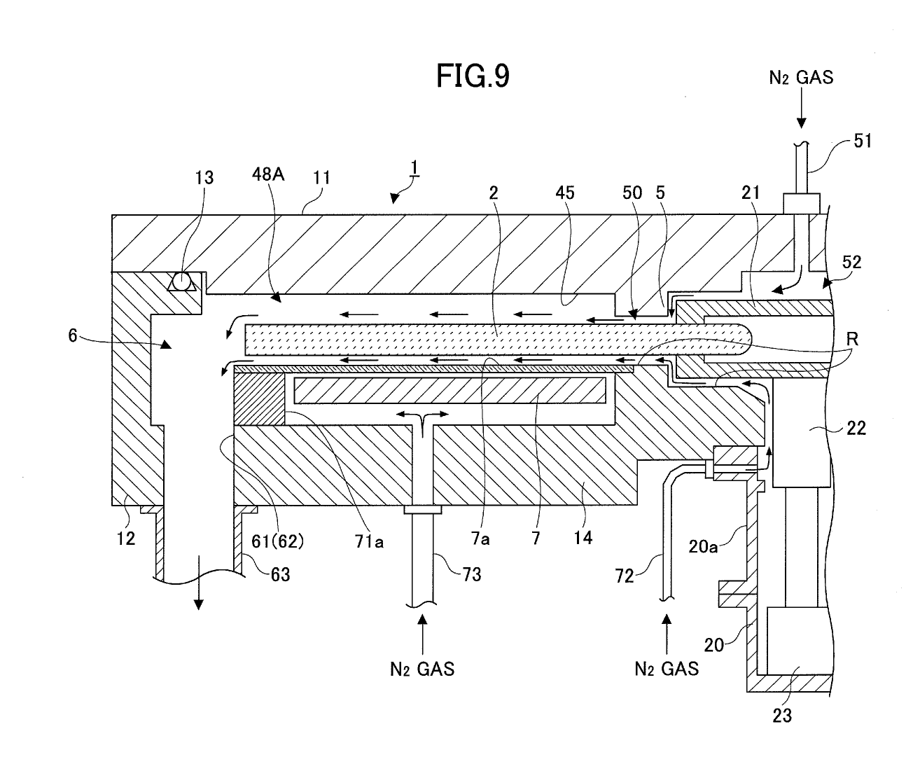

Referring to FIG. 9, the bottom portion 14 of the chamber body 12 has the raised portion whose upper surface comes close to the turntable 2 and the core portion 21, leaving slight gaps between the raised portion R and the turntable 2 and between the raised portion R and the core portion 21. In addition, the bottom portion 14 has a center opening through which the rotational shaft 22 extend. An inner diameter of the center opening is slightly larger than the diameter of the rotational shaft 22, leaving a slight gap that is in pressure communication with the case body 20 through the flanged pipe portion 20a. A purge gas supplying pipe 72 is connected to an upper portion of the flanged pipe portion 20a.

With the above configurations, N₂ gas flows into a space between the turntable 2 and the protection plate 7a from the purge gas supplying pipe 72 through the slight gap between the rotational pipe 22 and the center opening of the bottom portion 14, the slight gap between the core portion 21 and the raised portion R of the bottom portion 14, and the slight gap between the raised portion of the bottom portion 14 and the turntable 2. In addition, the N₂ gas is also supplied to the space where the heater unit 7 is housed from the purge gas supplying pipes 73. Then, these N₂ gases flow into the evacuation port 61 through a gap between the block member 71a and the lower surface of the turntable 2. Such N₂ gases serve as the separation gas that impedes the BTBAS (or O₃) gas from flowing around the turntable 2 to be intermixed with the O₃ (or BTBAS) gas.

Incidentally, because FIG. 9 corresponds to a left half of FIG. 1, which is a cross-sectional view taken along the A-A line in FIG. 3, and illustrates the first area 48A, the convex portion 4 is not illustrated in FIG. 9. On the other hand, the protrusion portion 5 is illustrated slightly above the center portion of the turntable 2 in the first area 48A in FIG. 9. Even in this case, the pressure of the space 50 between the protrusion portion 5 and the turntable 2 is maintained higher than that of the first area 48A by the N₂ gas from the separation gas supplying nozzle 51. With this, the N₂ gas flows into the first area 48A from the space 50 and along the upper surface of the turntable 2.

Referring to FIGS. 2, 3, and 10, a transfer opening 15 is formed in the circumferential wall of the chamber body 12. Through the transfer opening 15, the wafer W is transferred into or out from the vacuum chamber 1 by a transfer arm 10. The transfer opening 15 is provided with a gate valve (not shown) by which the transfer opening 15 is opened or closed.

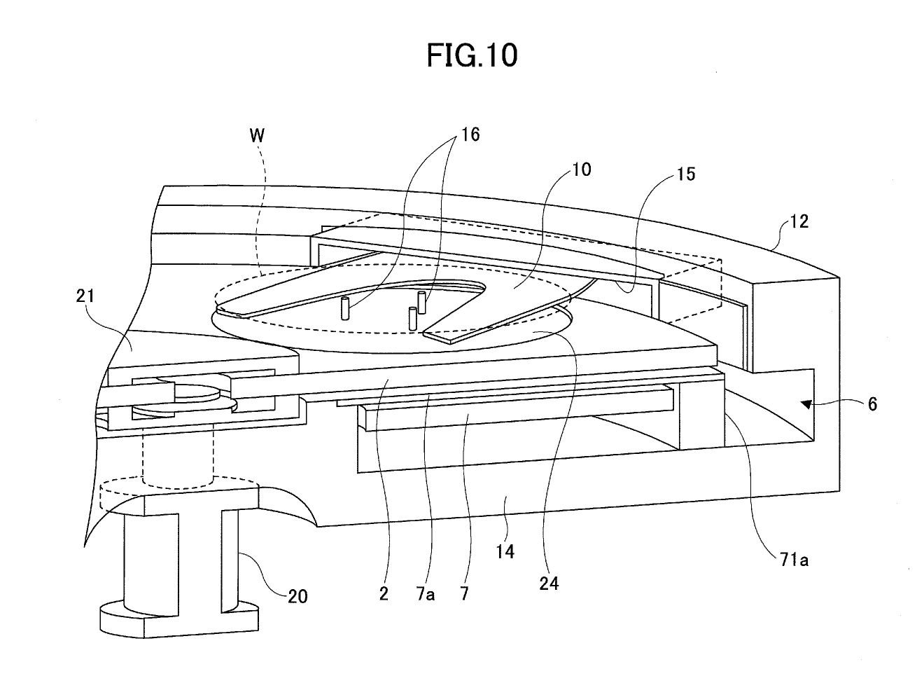

In addition, three through holes (not shown) are formed in the bottom of the concave portion 24, and three lift pins 16 (see FIG. 10) are moved upward and downward through the corresponding through holes by an elevation mechanism (not shown). The lift pins 16 support and move the wafer W, in order to transfer the wafer W from or to the transfer arm 10.

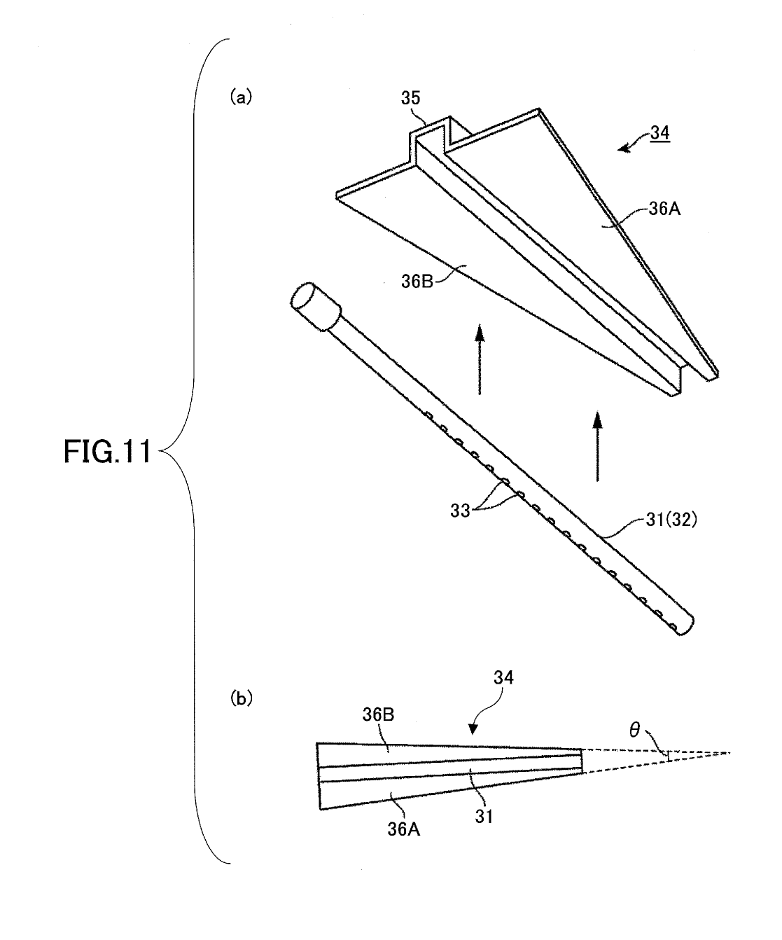

Next, the nozzle cover 34 attached to the reaction gas nozzle 31 is explained with reference to FIG. 11. The nozzle cover 34 extends in the longitudinal direction of the reaction gas nozzles 31 (or 32) and has a base portion 35 having a cross-sectional shape of “U”. The base portion 35 is arranged in order to cover the reaction gas nozzle 31 (or 32). The base portion 35 has a flow regulator plate 36A attached in one of two edge portions extending in the longitudinal direction of the base portion 35 and a flow regulator plate 36B in the other of the two edge portions.

As clearly illustrated in Section (b) of FIG. 11, the flow regulatory plates 36A, 36B are bilaterally symmetric with respect to the center axis of the reaction gas nozzle 31 (or 32). In addition, lengths of the flow regulatory plates 36A, 36B along the rotation direction of the turntable 2 become longer in a direction from the center to the circumference of the turntable 2, so that the nozzle cover 34 has substantially a sector top view shape. A center angle of the sector shape that is shown by a dotted line in Section (b) of FIG. 5 may be determined taking into consideration a size of a convex portion 4 (separation area D). For example, the center angle is preferably, for example, greater than or equal to 5° and less than 90°, or more preferably greater than or equal to 8° and less than 10°.

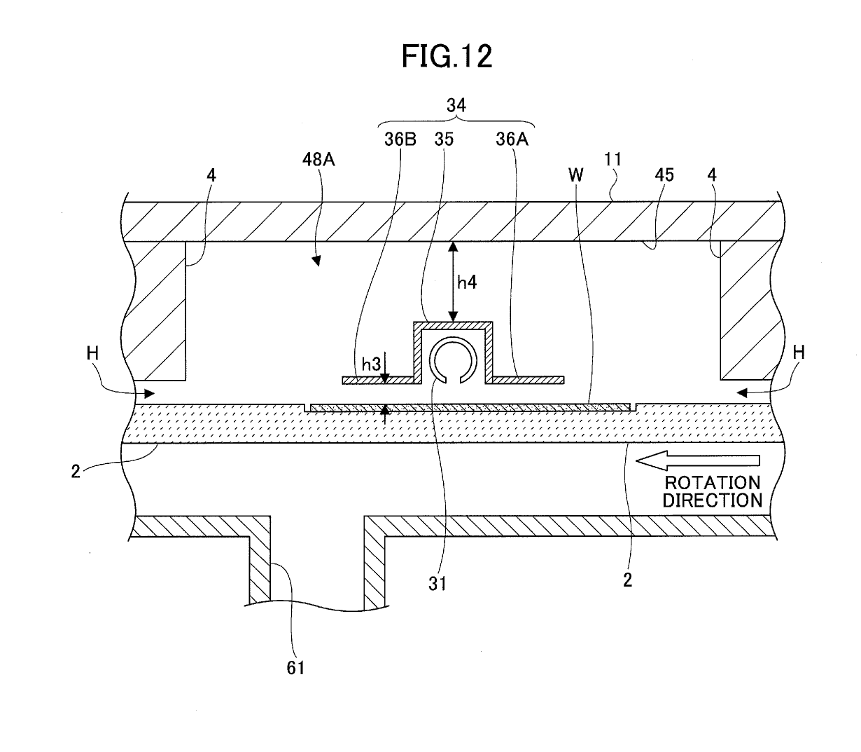

FIG. 12 illustrates the inside of the vacuum chamber 1 seen from the longitudinal direction of the reaction gas nozzle 31. As shown, the flow regulatory plates 36A, 36B are attached to the reaction gas nozzle 31 (or 32) in order to be parallel with and close to the upper surface of the turntable 2. A height h3 of the flow regulatory plates 36A, 36B from the upper surface of turntable 2 may be, for example, from 0.5 mm through 4 mm, while a height of the high ceiling surface 45 from the upper surface of the turntable 2 is, for example, from 15 mm through 150 mm. A distance h4 between the base portion 35 of the nozzle cover 34 and the high ceiling surface 45 may be, for example, from 10 mm through 100 mm. In addition, the flow regulatory plate 36A is arranged upstream relative to the rotation direction of the turntable 2 in relation to the reaction gas nozzle 31 (or 32), and the flow regulatory plate 36B is arranged downstream relative to the rotation direction of the turntable 2 in relation to the reaction gas nozzle 31 (or 32). With these configurations, the N₂ gas flowing out from the space H below the convex portion 4 to the first area 48A is guided toward a space above the reaction gas nozzle 31 (or 32) or the base portion 35 of the nozzle cover 34 by the flow regulatory plate 36A, and is less likely to flow into the process area P1 (or P2) below the reaction gas nozzle 31 (or 32). Therefore, the BTBAS gas (or the O₃ gas) is less likely to be diluted by the N₂ gas (the separation gas).

Incidentally, because the separation gas flows at higher speed in an area near the circumference of the turntable 2 due to centrifugal force generated by the rotation of the turntable 2, the separation gas may flow into the process area P1 (or P2) in the area near the circumference of the turntable 2. However, because the flow regulatory plate 36A becomes wider in a direction from the center to the circumference of the turntable 2, as shown in Section (a) of FIG. 11, the separation gas is impeded from flowing into the process area P1.

Referring again to FIG. 3, the film deposition apparatus according to this embodiment is provided with a control portion 100 that controls the entire film deposition apparatus. The control portion 100 includes a process controller 100a composed of, for example, a computer, a user interface portion 100b, and a memory device 100c. The user interface portion 100b has a display that shows operational status of the film deposition apparatus, a keyboard or a touch panel (not shown) that is used by an operator in order to modify process recipes or by a process manager in order to modify process parameters, and the like.

The memory device 100c stores control programs that cause the process controller 100a to perform various film deposition processes, process recipes, parameters and the like to be used in the various processes. The programs include a group of instructions for causing the film deposition apparatus to perform operations described later. The control programs and process recipes are stored in a storage medium 100d such as a hard disk, a compact disk (CD), a magneto-optic disk, a memory card, a flexible disk, a semiconductor memory or the like, and loaded into the control portion 100 from the storage medium 100d through corresponding input/output (I/O) devices. In addition, the programs and recipes may be downloaded to the memory device 100c through a communication line.

Next, operations of the film deposition apparatus (a film deposition method) according to the embodiment of the present invention are explained with reference to the drawings previous referred to. First, one of the concave portions 24 is aligned with the transfer opening 15 (FIG. 10) by rotating the turntable 2, and the gate valve (not shown) is opened. Next, the wafer W is transferred into the vacuum chamber 1 by the transfer arm 10 through the transfer opening 15. Then, the lift pins 16 are brought upward to receive the wafer W from the transfer arm 10, and the transfer arm 10 retracts from the vacuum chamber 1. After the gate valve (not shown) is closed, the lift pins 16 are brought downward by a lift mechanism (not shown) so that the wafer W is brought downward into the wafer receiving portion 24 of the turntable 2. Such operations are repeated by intermittently rotating the turntable 2, and five wafers W are placed in the corresponding concave portions 24 of the turntable 2.

Then, the N₂ gas is supplied from the separation gas nozzles 41, 42; the N₂ gas is supplied from the separation gas supplying pipe 51 and the purge gas supplying pipes 72, 73; and an inner pressure of the vacuum chamber 1 is set at a predetermined process pressure by the pressure adjusting portion 65 and the vacuum pump 64 (FIG. 1). Concurrently or subsequently, the turntable 2 starts rotating clockwise when seen from above at a predetermined rotation speed. The turntable 2 is heated to a predetermined temperature (for example, 300° C.) by the heater unit 7 in advance, and the wafers W can also be heated at substantially the same temperature by being placed on the turntable 2. After the wafers W are heated and maintained at the predetermined temperature, the O₃ gas is supplied to the process area P2 from the reaction gas nozzle 32 and the BTBAS gas is supplied to the process area P1 from the reaction gas nozzle 31.

While the BTBAS gas and the O₃ gas are continuously supplied, when the wafer W passes through the process area P1 below the reaction gas nozzle 31 due to the rotation of the turntable 2, the BTBAS gas is adsorbed on the wafer W, and the O₃ gas is adsorbed on the wafer W when the wafer W passes through the process area P2 below the reaction gas nozzle 32, and thus the BTBAS gas on the wafer W is oxidized by the O₃ gas. Namely, when the wafer W passes through both the first process area P1 and the second process area P2 once, a monolayer (two or more monolayers) of silicon oxide is formed on the wafer W. Then, the wafer W alternatively passes through the process area P1 and the process area P2 plural times, and thus a silicon oxide film having a predetermined thickness is deposited on the wafer W. After the silicon film having the predetermined thickness is deposited, the supplying of the BTBAS gas and O₃ gas is stopped, and the rotation of the turntable 2 is stopped. Next, the wafers W are transferred out from the vacuum chamber 1 by the transfer arm 10 and lift pins 16 in an opposite manner to that when the wafers W were transferred into the vacuum chamber 1. With this, the film deposition process is completed.

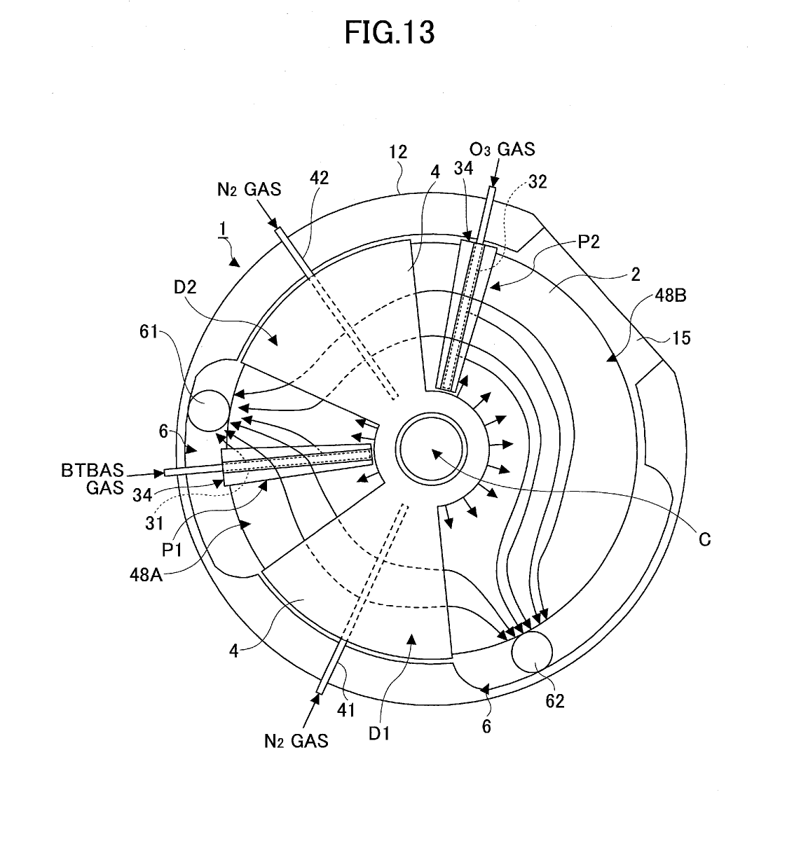

Next, a gas flow pattern in the vacuum chamber 1 is explained with reference to FIG. 13. The N₂ gas ejected from the separation gas nozzle 41 in the separation area D1 flows out in a direction substantially perpendicular to the radius direction of the turntable 2 from the space H (see Section (a) of FIG. 4) between the convex portion 4 and the turntable 2 to the first and the second areas 48A, 48B. The N₂ gas from the separation gas supplying nozzle 51 (see FIGS. 5 and 9) flows in a normal direction with respect to the outer circumferential surface of the protrusion portion 5 from the center separation area to the first and the second areas 48A, 48B.

The N₂ gas flowing out from the separation area D1 to the first area 48A flows mainly into the evacuation port 61 provided in the first area 48A by way of the space between the ceiling surface 45 and the nozzle cover 34 attached to the reaction gas nozzle 31. In addition, the N₂ gas flowing out from the center separation area C to the first area 48A flows in the radius direction of the turntable 2, and further into the evacuation port 61. Moreover, the N₂ gas flowing out from the separation area D2 to the first area 48A is mainly evacuated toward and finally into the evacuation port 61 before reaching the reaction gas nozzle 31. In such a manner, the N₂ gas serving as the separation gas, which creates the pressure barrier, from the separation areas D1, D2 and the center separation area C finally flows into the evacuation port 61 by way of the first area 48A.

The reaction gas nozzles 31, 32 supply the BTBAS gas and the O₃ gas, respectively, to the wafer W from slightly above the upper surface of the wafer W and the turntable 2. In this embodiment, the reaction gas nozzles 31, 32 having the corresponding nozzle covers 34 supply the BTBAS gas and the O₃ gas, respectively to the wafer W from slightly above the upper surface of the wafer W, but the BTBAS gas and the O₃ gas, respectively to the upper surface of the wafer W from slightly above the upper surface of the wafer W, even when the reaction gas nozzles 31, 32 have the corresponding nozzle covers 34. In addition, injectors or shower heads that supply the BTBAS gas and the O₃ gas, respectively to the wafer W from slightly above the upper surface of the wafer W may be used instead of the reaction gas nozzles 31, 32. When the reaction gases are supplied to the wafer W from slightly above the upper surface of the wafer W in such a manner, reaction gas concentrations can be directly controlled. If a gas nozzle is provided near the high ceiling surface 45 in the first area 48A (or the second area 48B), or through holes are formed in the ceiling plate 11 in order to supply the reaction gas to the wafer W, the reaction gas diffuses entirely in the first area 48A (or the second area 48B), and thus the reaction gas concentration is reduced near the upper surface of the wafer S. As a result, an insufficient amount of the BTBAS gas is adsorbed on the upper surface of the wafer W, or the BTBAS gas is insufficiently oxidized by the O₃ gas, thereby reducing the film deposition rate. Moreover, a relatively large amount of the BTBAS gas (or the O₃ gas) is evacuated from the evacuation port 61 (or 62) without contributing to the film deposition, which leads to a reduced reaction gas usage rate and thus a waste of the reaction gas.

In addition, the BTBAS gas ejected from the reaction gas nozzle 31 in the first area 48A flows through the inside space of the base portion 35 of the nozzle cover 34 and mainly the space below the flow regulatory plate 36B and further flows along the upper surface of the turntable 2. Then, this BTBAS gas flows in a flow direction restricted by the N₂ gas from the separation area D2 and the N₂ gas from the center separation area D1, and is evacuated from the evacuation port 61 along with these N₂ gases. Therefore, the BTBAS gas is not likely to flow into the second area 48B through the separation areas D1, D2 and the center separation area C. In addition, because the flow regulatory plates 36A, 36B are arranged slightly above the turntable 2, the N₂ gas flows over the reaction gas nozzle 31 (and the nozzle cover 34), and is not likely to flow into the space below the reaction gas nozzle 31 (the process area P1). Therefore, the BTBAS gas is not likely to be diluted by the N₂ gas (or the separation gas).

On the other hand, the N₂ gas flowing out from the separation area D2 to the second area 48B flows toward the evacuation port 62, while being pushed outward by the N₂ gas from the center separation area C, and is finally evacuated from the evacuation port 62. In addition, the O₃ gas ejected from the reaction gas nozzle 32 in the second area 48B flows in the same manner and is finally evacuated from the evacuation port 62.

Incidentally, when the reaction gas nozzle 32 is not provided with the nozzle cover 34, the N₂ gas may flow through the process area P2 below the reaction gas nozzle 32 in the second area 48B, the O₃ gas ejected from the reaction gas nozzle 32 may be diluted. However, because the second area 48B is greater than the first area 48A and the reaction gas nozzle 32 is as far away from the evacuation port 62 as possible in this embodiment, the O₃ gas can fully react with (or oxidize) the BTBAS gas adsorbed on the wafer W while the O₃ gas is ejected from the reaction gas nozzle 32 and evacuated from the evacuation port 62. Namely, the dilution of the O₃ gas by the N₂ gas is not a seriously problem.

In addition, while part of the O₃ gas ejected from the reaction gas nozzle 32 can flow toward the separation area D2, this part of the O₃ gas cannot flow into the separation area D2 because the space H of the separation area D2 has a higher pressure than the second area D2. Thus, this part of the O₃ gas flows along with the N₂ gas from the separation area D2 toward the evacuation port 62 and is evacuated from the evacuation port 62. Moreover, another part of the O₃ gas flowing from the reaction gas nozzle 32 toward the evacuation port 62 may flow toward the separation area D1, but cannot flow into the separation area D1 from the same reasons above. Namely, the O₃ gas cannot flow through the separation areas D1, D2 to reach the first area 48A, and thus the O₃ and the BTBAS gas are impeded from being intermixed with each other.

As shown by arrows in FIG. 13, the BTBAS gas and the N₂ gas converge in the first area 48A; and the converged gas flows in the first area 48A along the rotation direction of the turntable 2 and is evacuated from the evacuation port 61 formed outside of the first area 48A. In addition, the O₃ gas and the N₂ gas converge in the second area 48B; and the converged gas flows in the second area 48B along the rotation direction of the turntable 2 and is evacuated from the evacuation port 62 formed outside of the second area 48B.

### Modified Example

Modified examples of several members or components in the film deposition apparatus according to the embodiment are explained in the following.

While the convex portion 4 is provided with the bent portion 46 that fills out the space between the turntable 2 and the chamber body 12 in the separation areas D1, D2 as shown in FIG. 5, an inner circumferential surface of the chamber body 12 may be expanded to come close to the turntable 2 in the separation areas D1, D2. In this case, a gap between the expanded inner surface 46a and the turntable 2 may be smaller than or equal to the height h1 of the low ceiling surface 44. With this, the same effect as the bent portion can be provided.

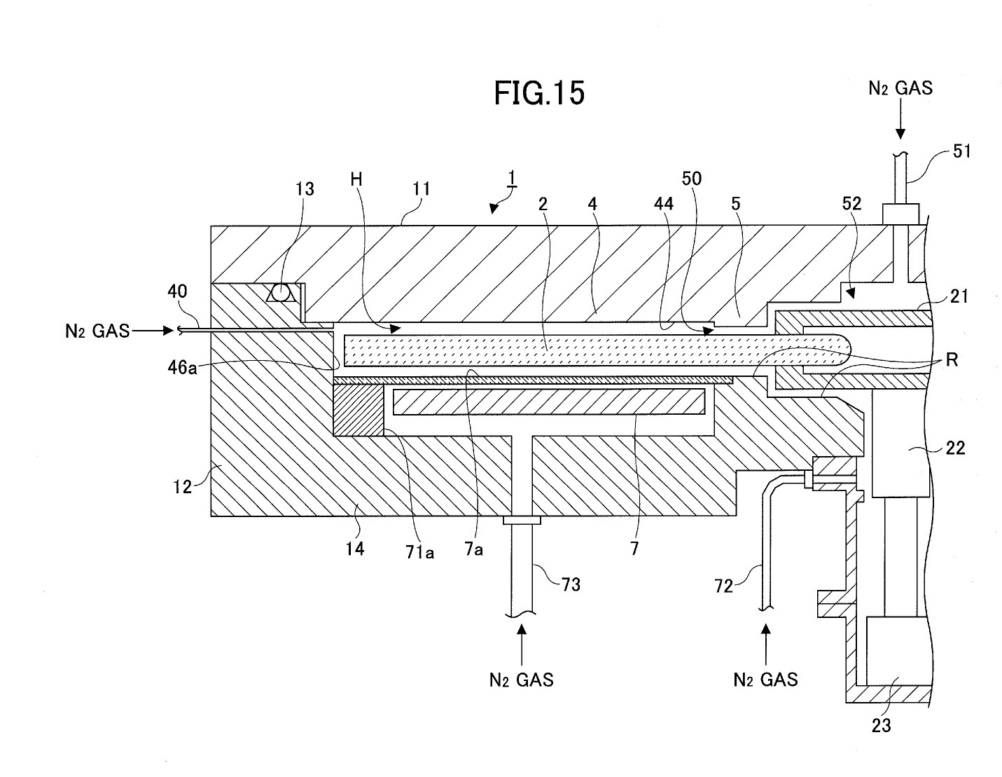

In addition, the nozzle 40 that goes through the circumferential wall of the chamber body 12 may be provided as shown in FIG. 15, and N₂ gas may be supplied to the space H of the separation area D1 (or D2) from the nozzle 40. With this, the N₂ gas ejected from the separation gas nozzle 41 (or 42) is less likely to flow outward and be evacuated through the space between the turntable 2 and the inner circumferential wall of the chamber body 12. Namely, the N₂ gas supplied from the nozzle 40 contributes to maintaining the space H at a higher pressure than those of the first and the second areas 48A, 48B. Incidentally, plural of the nozzles 40 may be provided at predetermined angular intervals along the circumferential wall of the chamber body 12. In addition, while the nozzle 40 is open in the inner circumferential surface 46a in FIG. 15, the nozzle(s) 40 may pass through the bent portion 46 (FIG. 5) in order to supply the N₂ gas to the space H below the convex portion 4. Moreover, the nozzle(s) 40 may be provided instead of the separation gas nozzle 41 (or 42) in order to supply the N₂ gas to the space H.

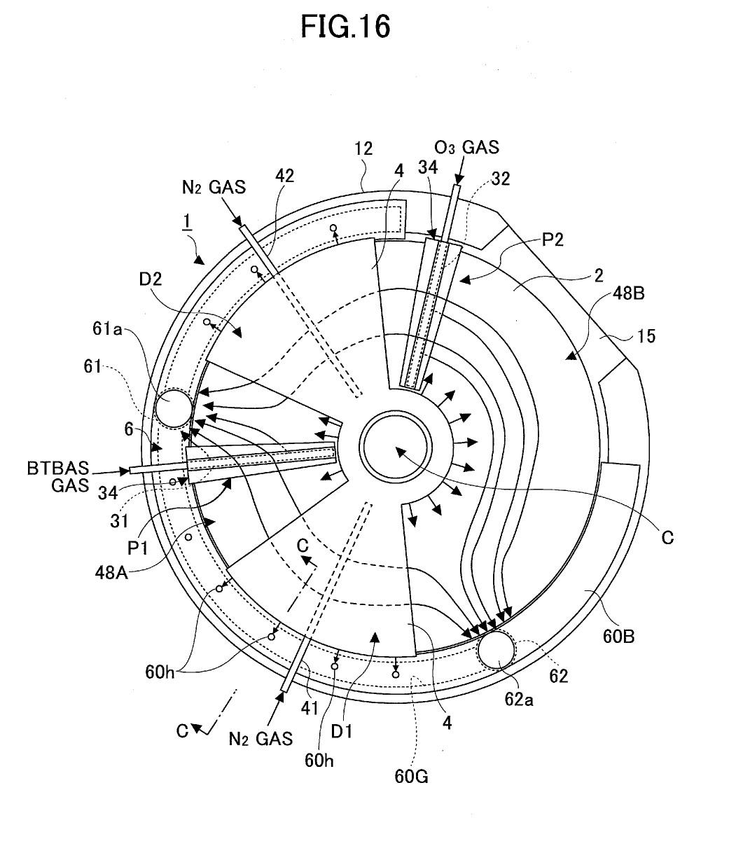

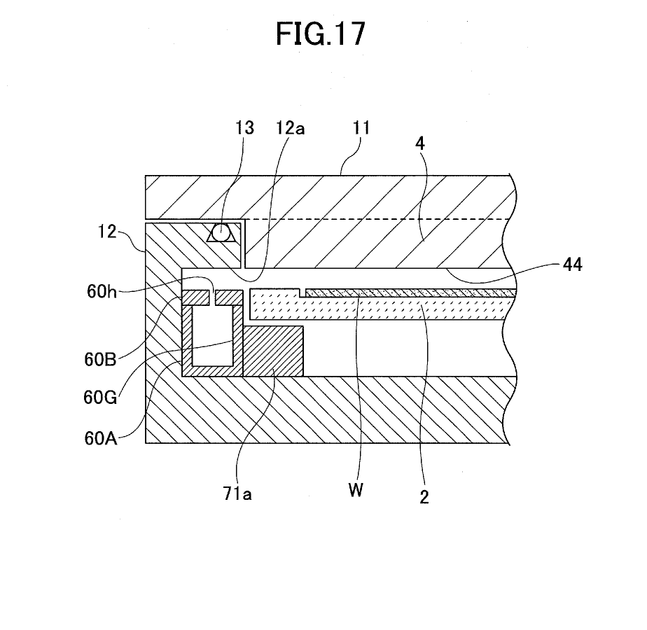

In addition, referring to FIG. 16 and FIG. 17 that is a cross-sectional view taken along a C-C line in FIG. 16, the inner circumferential wall of the chamber body 12 is indented outward in the separation area D1 (or D2), thereby creating a relatively large space between the turntable 2 and the chamber body 12. With this, a lower surface 12a is formed in the chamber body 12, as shown in FIG. 17. In addition, a baffle plate 60B is provided between the turntable 2 and the chamber body 12 in a part of the second area 48B, the separation area D1, the first area 48A, and the separation area D2. The baffle plate 60B has openings 61a, 62a corresponding to the evacuation ports 61, 62, which makes it possible to evacuate the first area 48A and the second area 48B, respectively. In addition, holes 60h having an inner diameter smaller than the inner diameters of the opening 61a, 62a are formed at predetermined intervals in the baffle plate 60B. A groove member 60A is provided below the baffle plate 60B. In the groove member 60A, a groove 60G is provided. The groove 60G is in pressure communication with the evacuation ports 61, 62. With this, a small amount of the N₂ gas can be evacuated through the holes 60h and the groove 60G from the separation area D1 (or D2).

However, a height of the lower surface 12a of the chamber body 12 from the baffle plate 60B may be substantially equal to the height h1 of the low ceiling surface 44 from the turntable 2, thereby providing a sufficient resistance against the N₂ gas flowing in the separation area D1 (or D2). Therefore, only a limited amount of the N₂ gas can be evacuated through the holes 60h. In addition, because the first area 48A and the second area 48B are evacuated by the corresponding evacuation ports 61, 62 (the corresponding openings 61a, 62a), which have the larger inner diameters than the holes 60h, the pressure of the spaces H (FIG. 4) below the convex portions 4 and the space 50 below the protrusion portion 5 (FIG. 5) are maintained higher than the first and the second areas 48A, 48B. In other words, the baffle plate 60B can restrict the N₂ gas flow toward the outer circumference of the turntable 2 in the separation area D1 (or D2). This is because the baffle plate 60B has the large openings 61a, 62a corresponding to the evacuation ports 61, 62 and the openings 60h, which have sufficiently small inner diameters than those of the openings 61a, 62a, in the separation areas D1, D2. Namely, the separation effect of the reaction gases can be provided even by the configuration shown in FIGS. 16 and 17. Incidentally, the small holes 60h are not necessarily formed in the baffle plate 60B, but the baffle plate 60B may be provided only with the openings 61a, 62a. In other words, the baffle plate 60B preferably has the openings 61a, 62a only, but may have the small holes 60h for the separation areas D1, D2, thereby evacuating the N₂ gas from the separation areas D1, D2, as long as the pressures of the spaces H in the separation areas D1, D2 and the space 50 of the center separation area C are maintained.

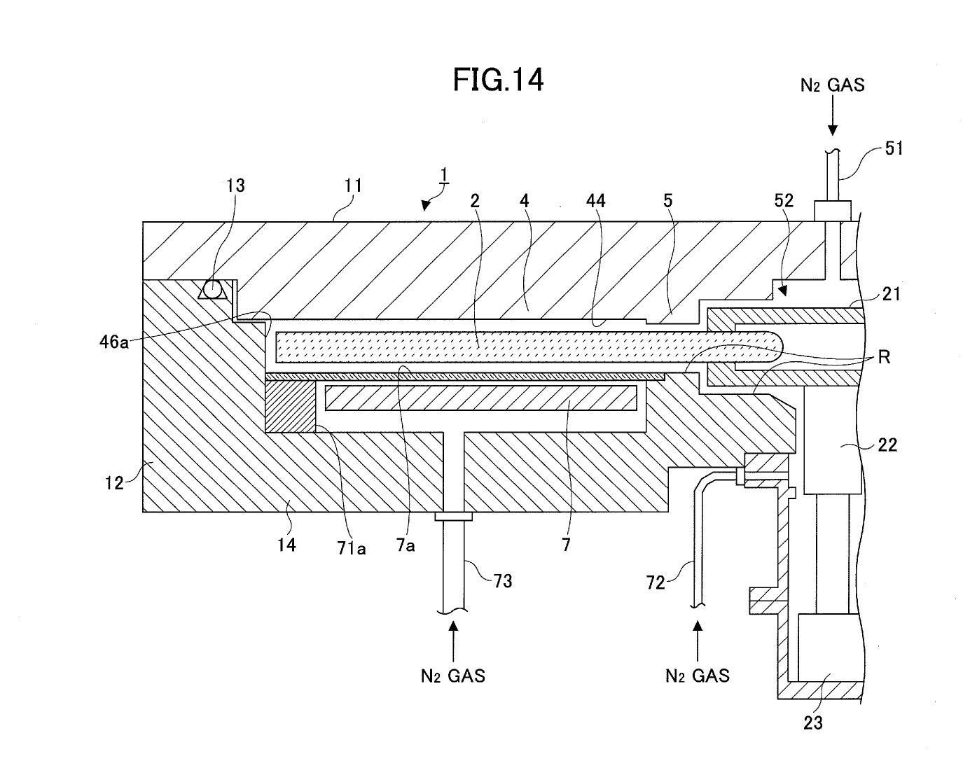

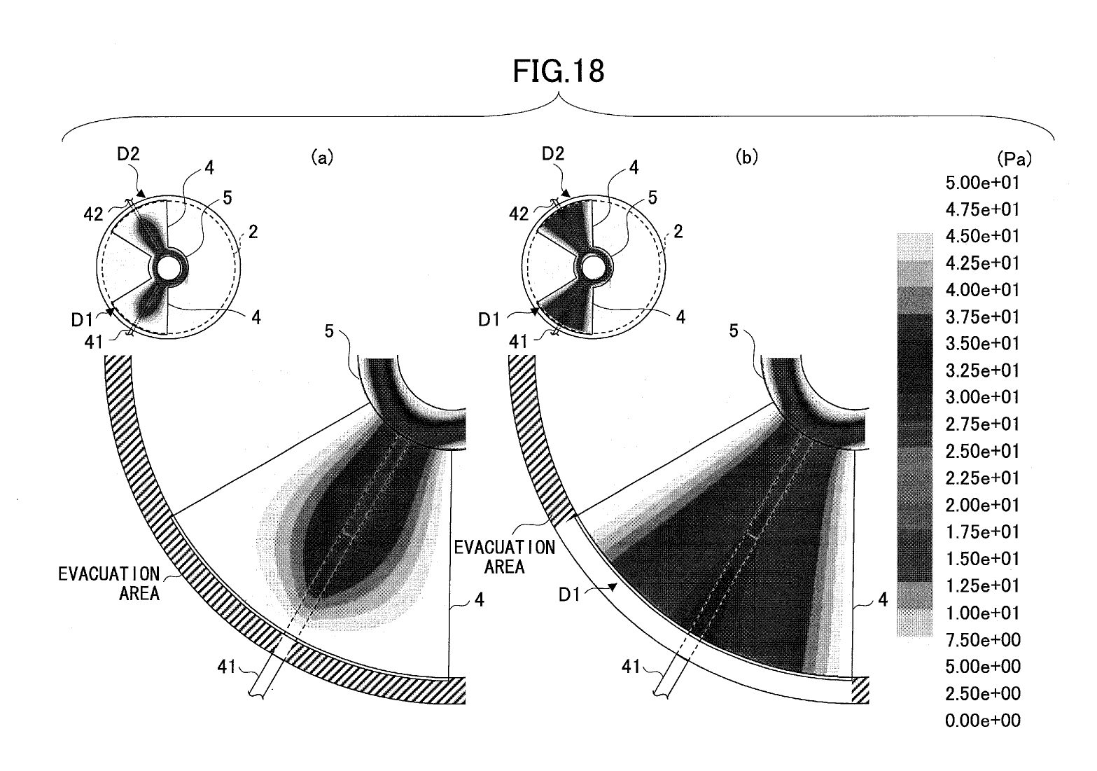

Incidentally, computer simulation was carried out about the pressures of the spaces H of the separation areas D1, D2 and the space 50 of the center separation area C when the vacuum chamber 1 is evacuated from an entire gap between the turntable 2 and the inner circumferential surface of the chamber body 12. The results are explained next. In this computer simulation, a vacuum chamber, which does not have the transfer opening 15 and which is evacuated from the entire gap between the turntable 2 and the chamber body 12, is used as a model. This vacuum chamber corresponds to a case where other evacuation ports and corresponding openings in the baffle plate 60B that provide the same evacuation performance are provided in the separation areas D1, D2 in FIG. 16. The results are shown in Section (a) of FIG. 18. On the other hand, another result of computer simulation was carried out using a model where the vacuum chamber 1 is evacuated only through the first and the second areas 48A, 48B but not through the gap between the turntable 2 and the chamber body 12 in the separation areas D1, D2. This model corresponds to cases where the bent portions 46 are provided between the turntable 2 and the chamber body 12 in the separation areas D1, D2 as shown in FIG. 5, where the inner circumferential surface 46a is expanded inward to come close to the circumference of the turntable 2 as shown in FIG. 14, and where the baffle plate 60B (specifically, the baffle plate 60B without the holes 60h) is provided between the turntable 2 and the chamber body 12 as shown in FIG. 16.

It can be understood by comparing Sections (a) and (b) of FIG. 18 that a high pressure area is smaller when the vacuum chamber is evacuated through the entire gap between the turntable 2 and the chamber body 12 than when the vacuum chamber 1 is evacuated through the first area 48A and the second area 48B. Specifically, a significant pressure reduction can be observed near the outer portion of the separation area D1 in Section (a) of FIG. 18. The smaller high pressure area and significant pressure reduction in the former case is because the vacuum chamber is evacuated through the outer portion of the separation area D1. The same discussions hold true for the separation area D1 as shown from inserts in Sections (a) and (b) of FIG. 18. From these results, it is seen to be advantageous when no evacuation ports are provided for the separation areas D1, D2.

Incidentally, when the holes 60h are provided in the baffle plate 60B as shown in FIG. 16, the inner diameters of the holes 60h should be small so that the pressures of the spaces H of the separation areas D1, D2 are not reduced. In addition, the pressures of the spaces H of the separation areas D1, D2 can preferably be maintained by providing the nozzle(s) 40 shown in FIG. 15 in order to supply the N₂ gas to the spaces H, which is easily understood from the computer simulation results.

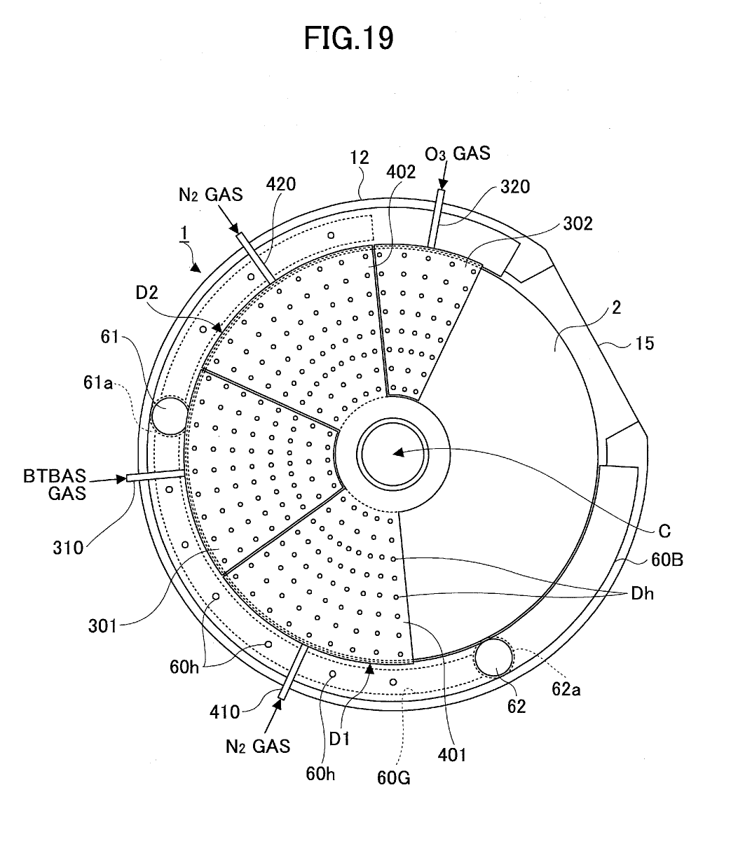

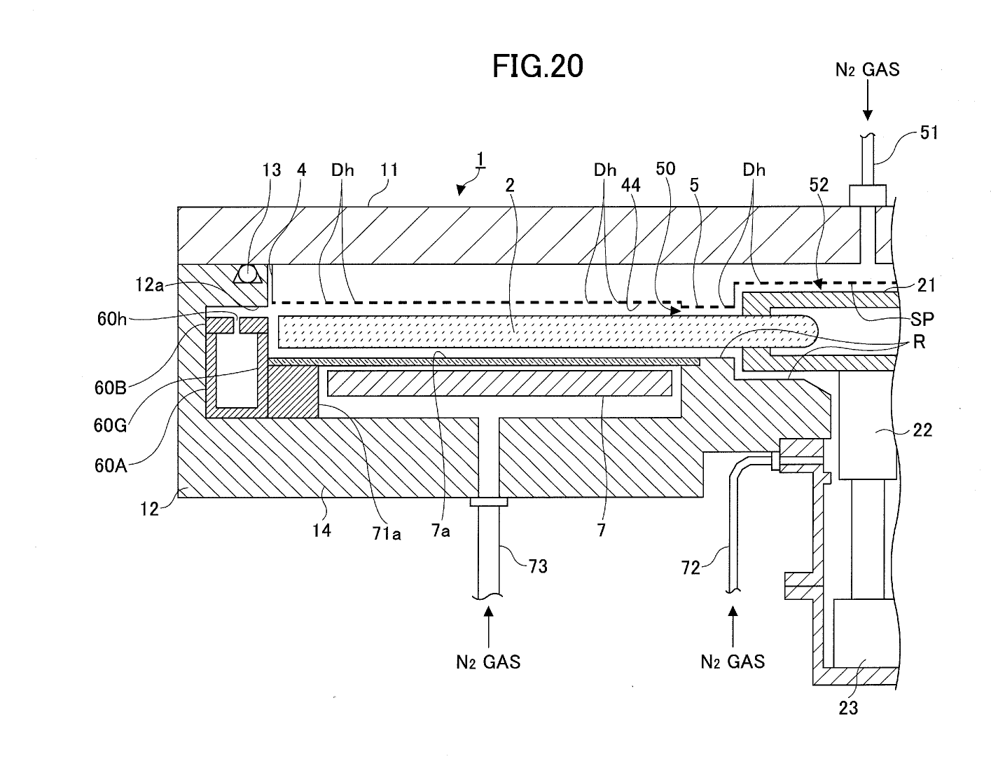

Next, a modified example of the separation areas D1, D2 is explained with reference to FIGS. 19 and 20. Referring to FIG. 19, a showerhead 401 having plural ejection holes Dh that eject N₂ gas toward the turntable 2 is provided in order to oppose the turntable 2 in the separation area D1, instead of the convex portion 4 and the separation gas nozzle 41. In addition, a pipe 410 is provided in such a manner that the pipe 410 goes through the circumferential wall of the chamber body 12. The pipe 410 supplies the N₂ gas to the showerhead 401. Another showerhead 402 having the same configuration as the showerhead 401 is provided in the separation area D2, and also a pipe 420 having the same configuration is provided in order to supply N₂ gas to the showerhead 402. With these configurations, the spaces H of the separation areas D1, D2 can be maintained at higher pressures than those of the first and the second areas 48A, 48B. In addition, when heights of lower surfaces of the showerheads 401, 402 from the turntable 2 are determined to be as small as the height h1, the pressures of the separation areas D1, D2 may certainly be maintained higher than the first and the second areas 48A, 48B. Moreover, because the baffle plate 60B is provided in the vacuum chamber 1 shown in FIG. 19 in order to restrict the N₂ gas flow toward the circumference of the turntable 2, the pressures of the separation areas D1, D2 may more certainly be maintained higher.

In the modified example shown in FIG. 19, the pressure of the space 50 of the center separation area C can be maintained higher than those of the first and the second areas 48A, 48B by supplying the N₂ gas from the separation gas supplying pipe 51 to the space 50 through the space 52, in the same manner as explained with reference to FIG. 5. In addition, as shown in FIG. 20, the protrusion portion 5 may be configured as a ring-shaped showerhead, and a shower plate SP may be provided above the core portion 21. In this case, the showerhead 401, the protrusion portion 5 configured as the showerhead, the shower plate SP, and the showerhead 402 may be integrated, and the N₂ gas may be supplied only from the separation gas supplying pipe 51, or from the pipes 410, 420 and the separation gas supplying pipe 51.

Incidentally, a showerhead 301 is provided in the first area 48A in FIG. 19. The showerhead 301 has the same configuration as the showerheads 401, 402, and the BTBAS gas is supplied to the showerhead 301 from a pipe 310 that goes through the circumferential wall of the chamber body 12. With this, the BTBAS gas is supplied toward the turntable 2 from the showerhead 301. Even with this configuration, the BTBAS gas is impeded from flowing through the separation areas D1, D2 and the center separation area C because of the higher pressures in the areas D1, D2, and C. Therefore, the BTBAS gas cannot be intermixed with the O₃ gas. Similarly, a showerhead 302 may be provided in the second area 48B, and the O₃ gas may be supplied to the showerhead 302 from a pipe 320.

In addition, densities of the ejection holes formed in the showerheads 301, 302, 401, 402 are preferably determined taking into consideration the reaction gases to be used, the rotation speed of the turntable 2, and the like. For example, when the ejection holes are formed at higher density near the protrusion portion 5 in the showerheads 401, 402, the pressure can be maintained higher near a boundary between the space H and the space 50. In addition, when the ejection holes are formed at higher density near the circumference of the turntable 2 in the showerheads 401, 402, the pressure can be maintained higher near the circumference of the turntable 2 in the space H.

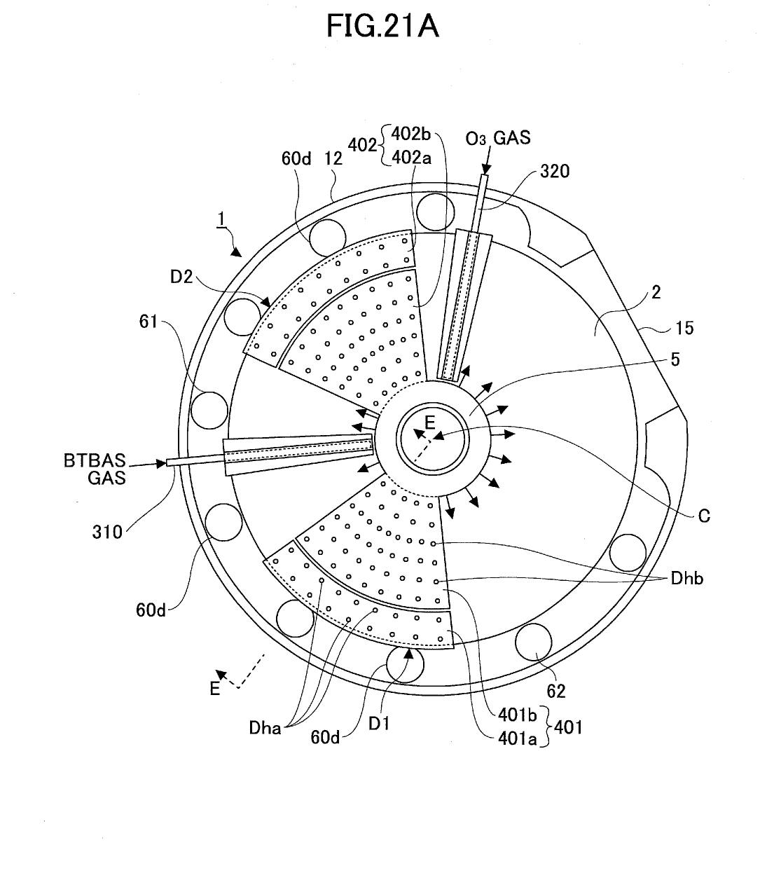

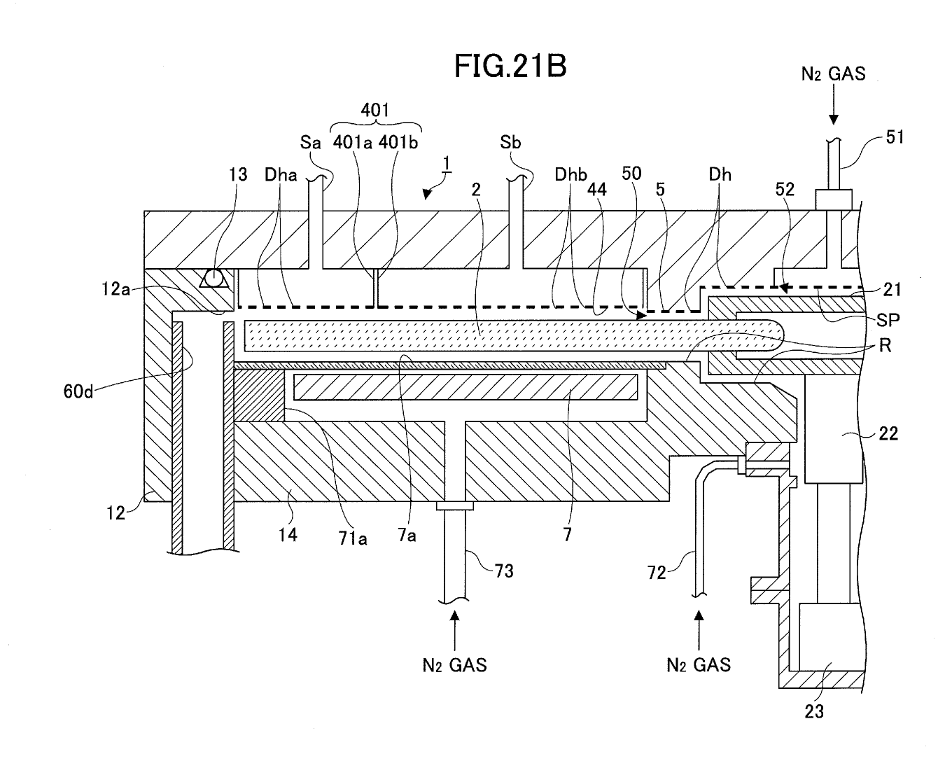

Next, another modified example of the separation areas D1, D2 is explained. Referring to FIG. 21A, the showerhead 401 in the first area D1 includes an outer portion 401a and an inner portion 401b that occupies the inner area of the outer portion 401a. As shown in FIG. 21B, which is a cross-sectional view taken along an E-E line of FIG. 21A, a supplying portion Sa that supplies the N₂ gas to the outer portion 401a through the ceiling plate 11 and a supplying portion Sb that supplies the N₂ gas to the inner portion 401b through the ceiling plate 1 are provided. With these configurations, a flow rate of the N₂ gas supplied from the supplying portion Sa to the outer portion 401a may be greater than a flow rate of the N₂ gas supplied from the supplying portion Sb to the inner portion 401b, thereby maintaining the pressure in the space below the outer portion 401a higher than in the space below the inner portion 401b. Therefore, the N₂ gas supplied to the space below the showerhead 401 is impeded from flowing toward the circumference of the turntable 2. In this case, an evacuation port 60d similar to the evacuation ports 61, 62 may be provided between the turntable 2 and the chamber body 12 in the separation area D1 as shown in FIGS. 21A and 21B, because the pressure reduction in the outer area of the separation area D1 can be avoided by the large flow rate of the N₂ gas supplied to the outer portion 401a.

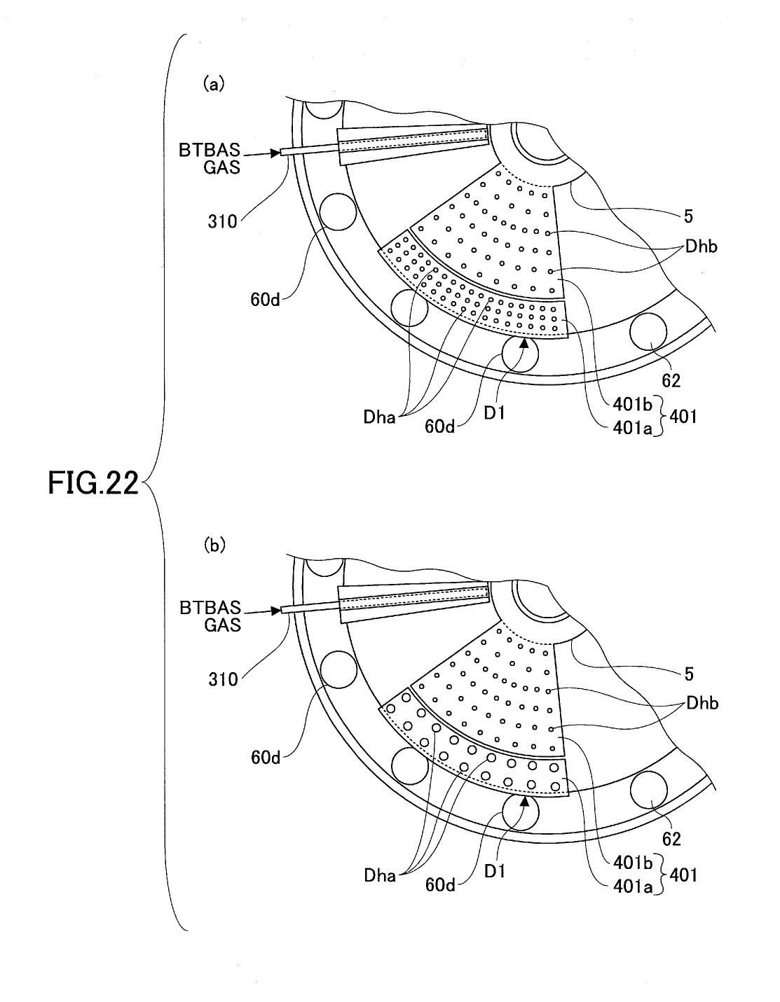

Incidentally, ejection holes Dha in the outer portion 401a and ejection holes Dhb in the inner portion 401b may have the same inner diameter. In this case, a density of the ejection holes Dha is preferably higher than a density of the ejection holes Dhb, as shown in Section (a) of FIG. 22. In addition, the density of the ejection holes Dha may be equal to the density of the ejection holes Dhb. In this case, the inner diameter of the ejection holes Dha is preferably larger than the inner diameter of the ejection holes Dhb. In other words, an opening ratio of a total opening area of the ejection holes Dha with respect to a plan-view area of the outer portion 401a is preferably greater than an opening ratio of a total opening area of the ejection holes Dhb with respect to a plan-view area of the inner portion 401b, in order to maintain the pressure below the outer portion 401a higher than the pressure below the inner portion 401b. In addition, the ejection holes Dha, Dhb may have, for example, circular shapes, oval shapes, or rectangular shapes. Even in these cases, the opening areas and the opening ratios are preferably determined so that the pressure below the outer portion 401a can be maintained higher than the pressure below the inner portion 401b.

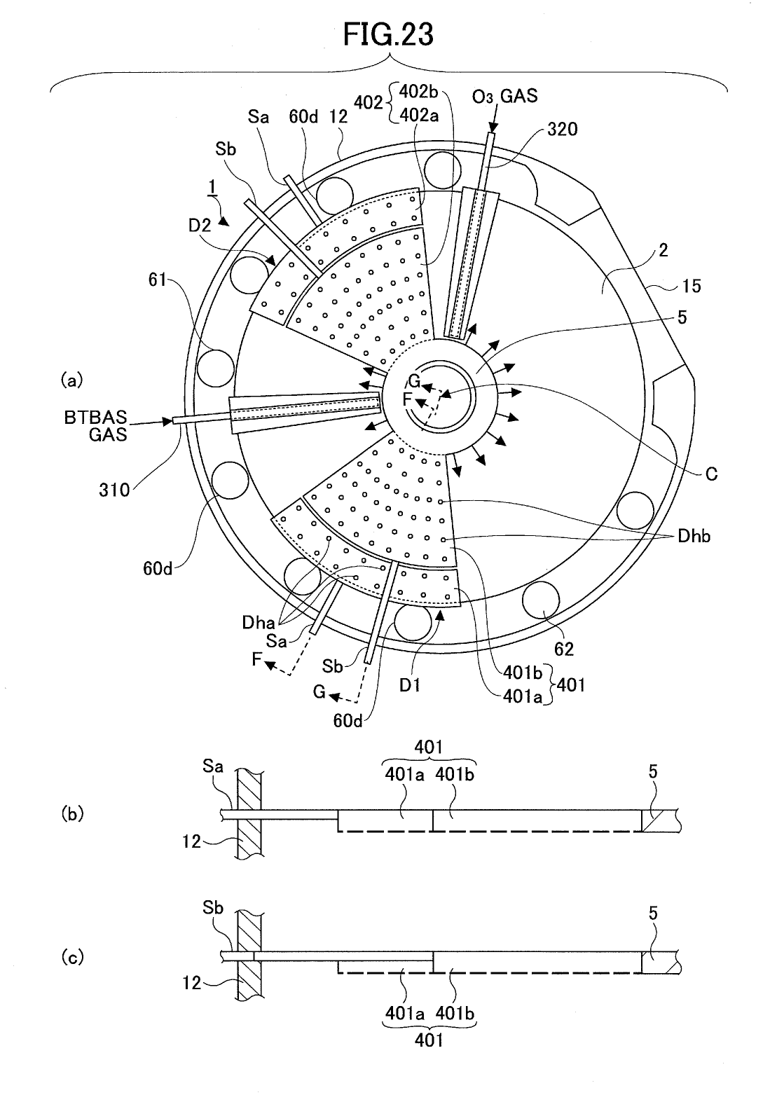

In addition, the pipes Sa, Sb may be introduced into the outer portion 401a and the inner portion 401b, respectively, through the circumferential wall of the chamber body 12, rather than through the ceiling plate 11, as shown in Section (a) of FIG. 23. Specifically, the pipe Sa goes through the circumferential wall of the chamber body 12 and is connected to the outer portion 401a, thereby supplying the N₂ gas to the outer portion 401a, as shown in Section (b) of FIG. 23. In addition, the pipe Sb goes through the circumferential wall of the chamber body 12 and the outer portion 401a and is connected to the inner portion 401b, thereby supplying the N₂ gas to the inner portion 401b, as shown in Section (c) of FIG. 23. Incidentally, Section (b) of FIG. 23 is a cross-sectional view taken along an F-F line in Section (a) of FIG. 23, and Section (c) of FIG. 23 is a cross-sectional view taken along a G-G line in Section (a) of FIG. 23.

Incidentally, while lengths of the outer portion 401a and the inner portion 401b along the radius direction of the turntable 2 are the same in the illustrated example, the lengths may be arbitrarily determined. In addition, while the above explanation is made for the separation area D1, the separation area D2 may be configured in the same manner.

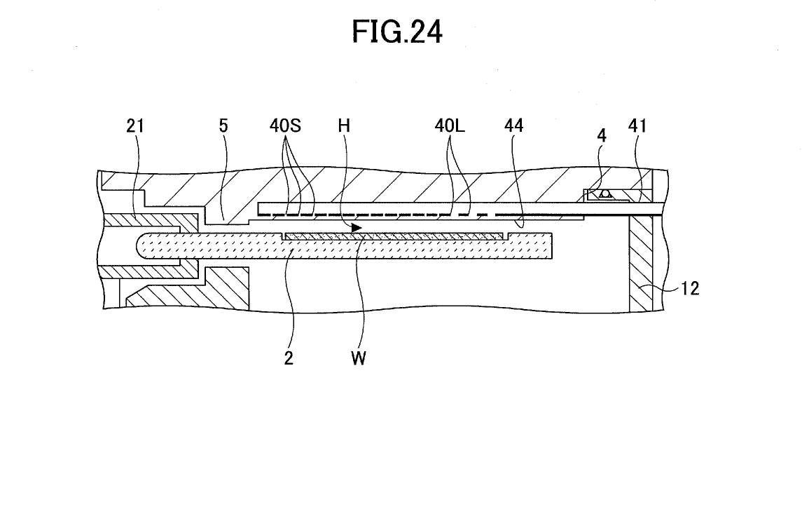

Moreover, the pressure reduction in the outer portion of the separation area D1 may be avoided by the following configurations. FIG. 24 is a cross-sectional view taken along the longitudinal direction of the separation gas nozzle 41 extending transverse to the rotation direction of the turntable (see FIG. 3 or the like). As shown, ejection holes 40L located in an outer portion of the separation gas nozzle 41 along the longitudinal direction have larger inner diameters, and ejection holes 40S located in an inner portion of the separation gas nozzle 41 along the longitudinal direction have smaller inner diameters. Here, the outer portion where the larger ejection holes 40L are formed may correspond to the length of the outer portion 401a (FIG. 23) along the radius direction of the turntable 2, and the inner portion where the small ejection holes 40S are formed may correspond to the length of the inner portion 401b (FIG. 23) along the radius direction of the turntable 2. With these configurations, a larger amount of the N₂ gas is supplied from the ejection holes 40L in the outer portion, and a smaller amount of the N₂ gas is supplied from the ejection holes 40S in the inner portion, thereby maintaining the pressure in the outer portion of the space H below the convex portion 4 higher than the inner portion of the space H. The separation area D2 may be configured in the same manner.

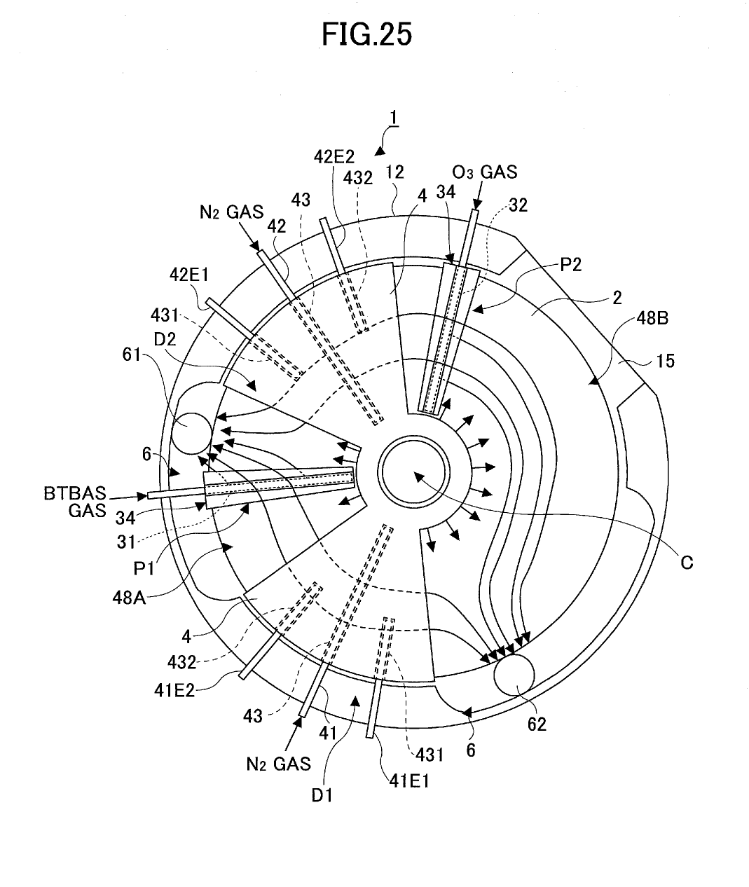

FIG. 25 illustrates the convex portion 4 in the separation area D1 and the separation gas nozzle 41 housed in the groove portion 43. The convex portion 4 has additional groove portions 431 and 432 that are located upstream and downstream relative to the rotation direction of the turntable 2 in relation to the groove portion 43, respectively. The groove portions 431, 432 have half a length of the groove portion 43. An auxiliary nozzle 41E1 is housed in the groove portion 431, and an auxiliary nozzle 41E2 is housed in the groove portion 432. The auxiliary nozzles 41E1, 41E2 are introduced into the corresponding grooves 431, 432 in the same manner as the separation gas nozzle 41. In addition, plural ejection holes (not shown) are formed at predetermined intervals in the auxiliary nozzles 41E1, 41E2 along longitudinal directions of the auxiliary nozzles 41E1, 41E2 in the vacuum chamber 1. The auxiliary nozzles 41E1, 41E2 are connected outside the vacuum chamber 1 to a N₂ gas supplying source (not shown). With these configurations, the N₂ gas is supplied from the auxiliary nozzles 41E1, 41E2 toward the turntable 2, thereby maintaining the pressure in the outer area, which corresponds to an area where the auxiliary nozzles 41E1, 41E2 extend, of the space below the convex portion 4 (space H) higher than those in the inner area of the space below the convex portion 4 (space H).

Incidentally, lengths of the groove portions 431, 432 and the auxiliary nozzles 41E1, 41E2 may be arbitrarily determined, without being limited to half the length of the separation gas nozzle 41. In addition, even in the separation area D2, the convex portion 4 may have the additional groove portions 431, 432 and the auxiliary nozzles 41E1, 41E2 may be housed in the corresponding groove portions 431, 432.

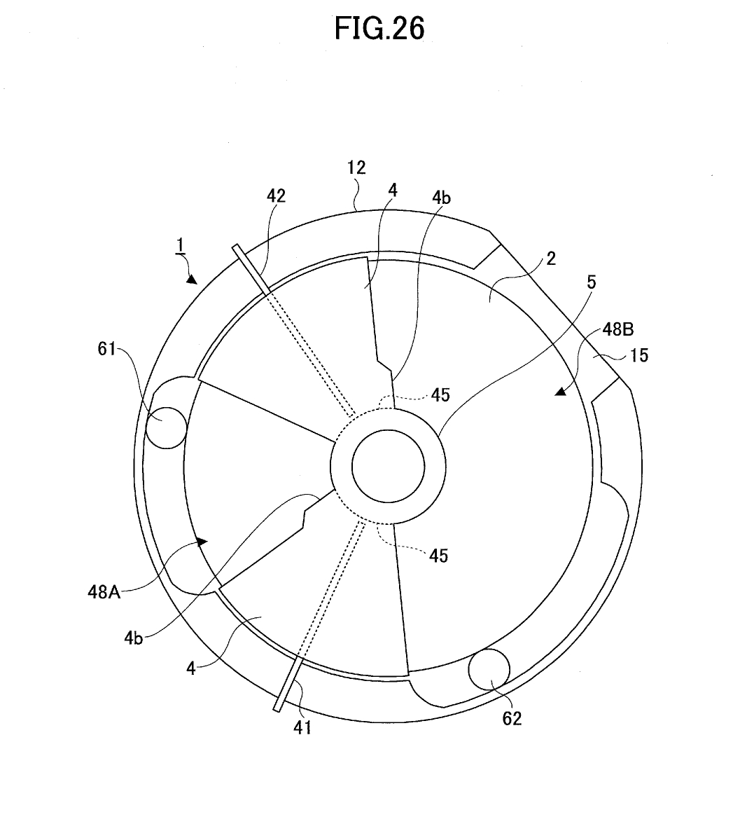

Next, a modified example of the convex portion 4 is explained. Referring to FIG. 26, the convex portion 4 has an extended portion 4b that extends in a direction downstream relative to the rotation direction of the turntable 2 from an inner portion near the protrusion portion 5. Therefore, when this convex portion 4 and the protrusion portion 5 are integrally formed as one member, this convex portion 4 and the protrusion portion 5 can provide a longer arc at a boundary 45 between this convex portion 4 and the protrusion portion 5. When this convex portion 4 and the protrusion portion 5 are made separately, this convex portion 4 and the protrusion portion 5 come in contact with each other at a large area therebetween. With these configurations, an area below the convex portion 4 and the protrusion portion 5, which has a higher pressure than the first and the second areas 48A, 48B can be expanded. Therefore, the BTBAS gas is more certainly impeded from flowing from the first area 48A to the second area 48B through the boundary 45 and its vicinity, and the O₃ gas is more certainly impeded from flowing from the second area 48B to the first area 48A through the boundary 45 and its vicinity. Incidentally, the convex portion 4 may have another extended portion that extends in a direction upstream relative to the rotation direction of the turntable 2 from an inner portion near the protrusion portion 5, in addition to or instead of the extended portion 4b shown in FIG. 26. In addition, a shape of the extended portion 4b may take various shapes, as long as the extended portion 4b can provide the longer boundary 45 between the convex portion 4 and the protrusion portion 5. For example, the boundary 45 may become longer when a side(s) of the convex portion 4, the side(s) extending along the radius direction of the turntable 2, is curved outward along a direction from the outer arc to the inner arc (the boundary 45) of the convex portion 4.

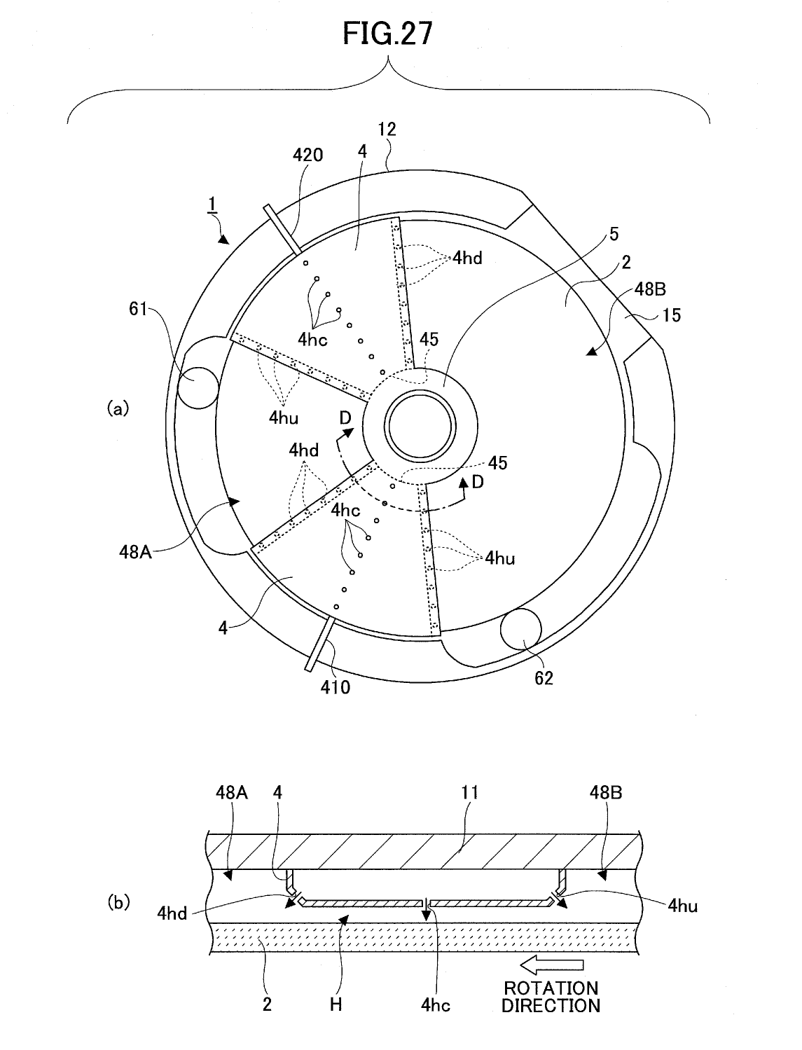

In addition, the convex portion 4 may be hollow. Referring to Section (a) of FIG. 27, a pipe 410 is connected to the hollow concave portion in order to supply the separation gas to the hollow convex portion 4. In the lower surface of the hollow convex portion 4 (the surface opposing the turntable 2), plural ejection holes 4hc are formed along an extended line of the pipe 410, and the N₂ gas supplied from the pipe 410 to the hollow convex portion 4 is ejected from the plural ejection holes 4hc toward the turntable 2. With this, the space below the hollow convex portion 4 can be maintained at a higher pressure than the first and the second areas 48A, 48B.

In addition, the lower surface of the hollow convex portion 4 may be slanted near the straight side edge, as shown in Section (b) of FIG. 27, which is a cross-sectional view taken along a D-D line in Section (a) of FIG. 27. In the slanted surface, ejection holes 4hu, 4hd are formed, so that the N₂ gas supplied to the hollow convex portion 4 can be ejected toward the turntable 2 through the ejection holes 4hu, 4hd, which can enhance the stream of the N₂ gas flowing outward from the space H to the first and the second areas 48A, 48B. Namely, the separation effect due to the N₂ gas (counter) flow can be enhanced, thereby avoiding the intermixture of the BTBAS gas and the O₃ gas in gaseous phase. Incidentally, the number of and sizes of the ejection holes 4hu, 4hd are arbitrarily determined taking into consideration the reaction gases to be used, the rotation speed of the turntable 2, or the like. For example, when the ejection holes 4hu, 4hd are formed in the slanted surface near the boundary 45 (Section (a) of FIG. 27) at a higher density, the pressure in the space H and the space 50 below the protrusion portion 5 near the boundary 45 can be maintained higher. When the ejection holes 4hu, 4hd are formed in the slanted surface near the circumference of the turntable 2 at a higher density, the pressure in the space H near circumference of the turntable 2 can be maintained higher. Incidentally, plural of the ejection holes 4hc may be distributed in the showerheads 301, 302, 401, 402 shown in FIG. 19.

In addition, an additional separation gas nozzle may be provided in parallel with the straight side of the convex portion 4 shown in FIGS. 3, 4, and 6, instead of using the hollow convex portion 4 shown in FIG. 27. The addition separation gas nozzle that has ejection holes that can eject N₂ gas has plural ejection holes open vertically toward the turntable 2, or open at a predetermined angle with respect to the vertical direction toward the turntable 2. With this configuration, the same effect as the hollow convex portion 4 shown in FIG. 27 can be provided.

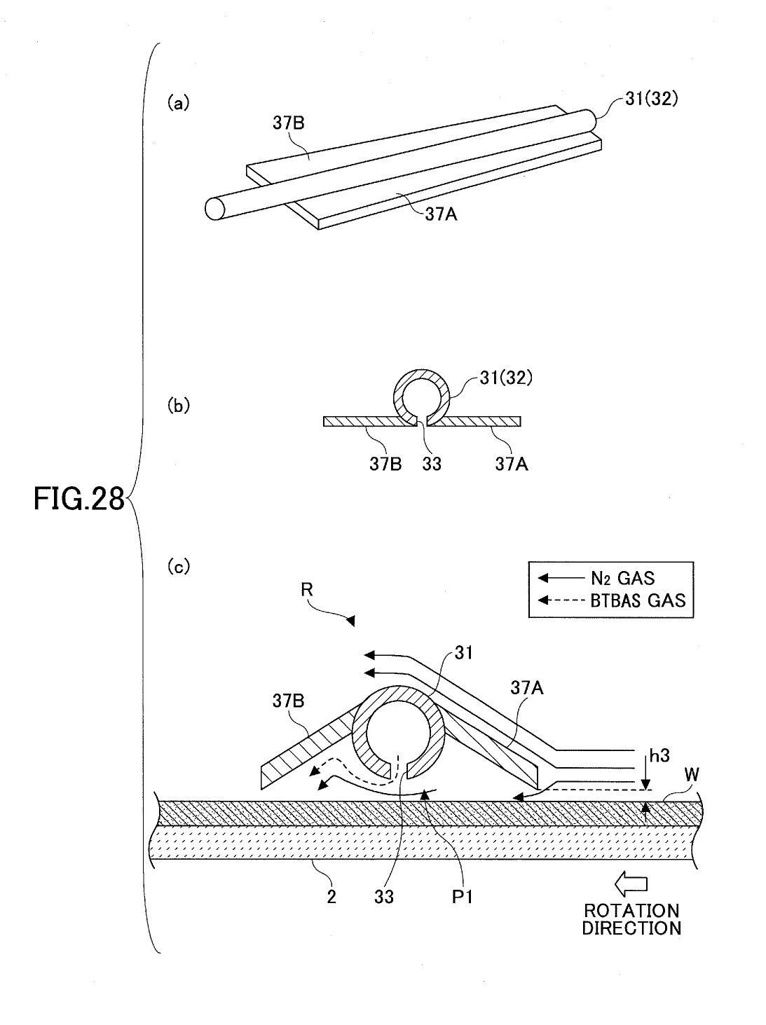

Next, a modified example of the nozzle cover 34 shown in FIG. 11 is explained. Referring to Sections (a) and (b) of FIG. 28, flow regulator plates 37A, 37B are attached to the reaction gas nozzles 31 (or 32) without using the base portion 35 (FIG. 11). In this case, the flow regulator plates 37A, 37B can be arranged away from the upper surface of the turntable 2 by the height h3 (FIG. 12), thereby providing the same effects as the nozzle cover 34. Even in this case, the flow regulator plates 37A, 37B may preferably have a top-view shape of a sector.

In addition, the flow regulator plates 36A, 36B, 37A, 37B are not necessarily parallel with the upper surface of the turntable 2. For example, the flow regulator plates 37A, 37B may be slanted from the upper portion of the reaction gas nozzle 31 toward the upper surface of the turntable 2, as shown in Section (c) of FIG. 28, as long as the height h3 of the flow regulator plates 37A, 37B from the upper surface of the turntable 2 is maintained so that the separation gas is likely to flow through the space above the reaction gas nozzle 31 (or 32) (see FIG. 13). The slanted flow regulator plate 37A shown in the drawing is preferable in order to guide the separation gas toward the space above the reaction gas nozzle 31 (or 32).

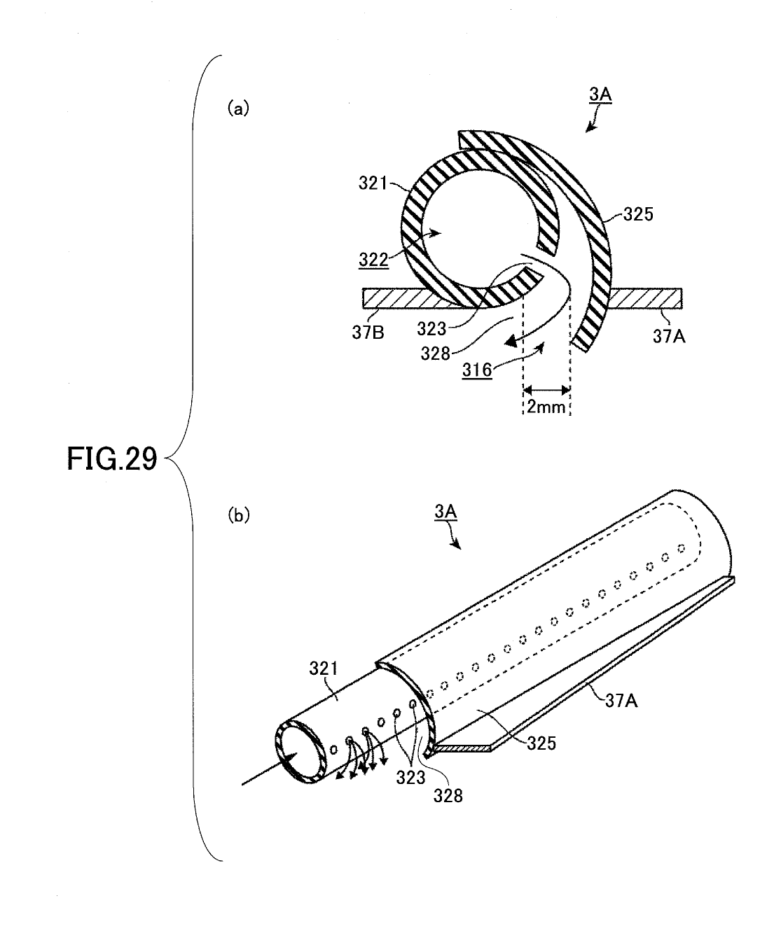

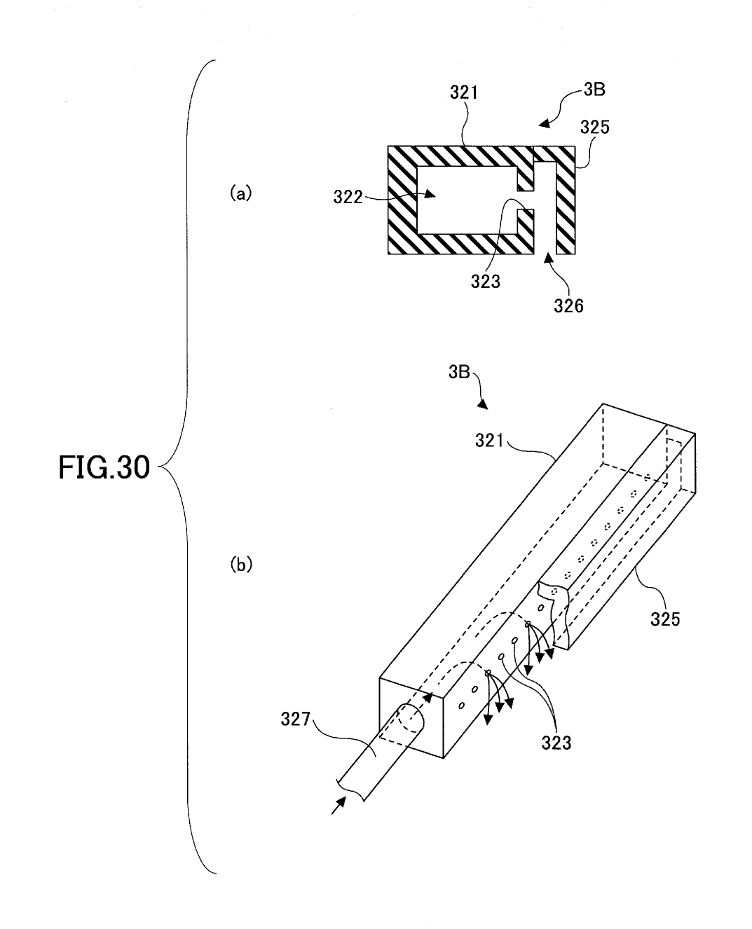

Next, other modified examples of the nozzle cover 34 are explained with reference to FIGS. 29 and 30. These modified examples may be considered as a reaction gas nozzle integrated with a nozzle cover, or a reaction gas nozzle having a function of the nozzle cover. To this end, the modifications are referred to as a reaction gas injector.

Referring to Sections (a) and (b) of FIG. 29, a reaction gas injector 3A includes a reaction gas nozzle 321 made of a circular cylindrical pipe in the same manner as the reaction gas nozzles 31, 32. In addition, the reaction gas nozzle 321 is provided in order to go through the circumferential wall of the chamber body 12 of the vacuum chamber 1 (FIG. 1), in the same manner as the reaction gas nozzles 31, 32. Moreover, the reaction gas nozzle 321 has plural ejection holes 323 each of which has an inner diameter of about 0.5 mm, and the ejection holes 323 are arranged at intervals of about 10 mm along the longitudinal direction of the reaction gas nozzle 321, in the same manner as the reaction gas nozzles 31, 32. However, the reaction gas nozzle 321 is different from the reaction gas nozzles 31, 32 in that the plural ejection holes 323 are open at a predetermined angle with respect to the upper surface of the turntable 2. In addition, a guide plate 325 is attached to an upper portion of the reaction gas nozzle 321. The guide plate 325 has a larger radius of curvature than that of the circular cylindrical pipe of the reaction gas nozzle 321. Because of the difference in the radii of curvature, a gas flow passage 316 is created between the reaction gas nozzle 321 and the guide plate 325. The reaction gas supplied from a gas supplying source (not shown) to the reaction gas nozzle 321 is ejected from the ejection holes 323 and reaches the upper surface of the wafer W (FIG. 13) placed on the turntable 2.

Moreover, the flow regulator plate 37A that extends in an upstream direction relative to the rotation direction of the turntable 2 is provided to a lower portion of the guide plate 325, and the flow regulator plate 37B that extends in a downstream direction relative to the rotation direction of the turntable 2 is provided to a lower end portion of the reaction gas nozzle 321.

The reaction gas injector so configured is arranged so that the flow regulator plates 37A, 37B are close to the upper surface of the turntable 2. Therefore, the separation gas is unlikely to flow into the process area (P1 or P2) and the separation gas is likely to flow through the space above the reaction gas injector 3A. Therefore, the reaction gas from the reaction gas injector 3A is not likely to be diluted by the N₂ gas.

Incidentally, when the reaction gas reaches the gas flow passage 316 through the ejection holes 323, the reaction gas hits the guide plate 325. As a result, the reaction gas spreads along the longitudinal direction of the reaction gas nozzle 321, as shown in Section (b) of FIG. 29, thereby making a concentration of the reaction gas uniform along the longitudinal direction in the reaction gas flow passage 326. Namely, this modified example is advantageous in that a film deposited on the wafer W can have excellent thickness uniformity.

Referring to Section (a) of FIG. 30, a reaction gas injector 3B has a reaction gas nozzle 321 made of a rectangular pipe. The reaction gas nozzle 321 has plural ejection holes 323, each of which has an inner diameter of 0.5 mm on one side wall. As shown in Section (b) of FIG. 30, the ejection holes 323 are arranged at intervals of 5 mm along a longitudinal direction of the reaction gas nozzle 321. In addition, a guide plate 325 having an L-shape is attached to the side wall where the ejection holes 323 are formed, so that there becomes a gap (e.g., about 0.3 mm) between the side wall and the guide plate 325.

In addition, as shown in Section (b) of FIG. 30, the reaction gas nozzle 321 is connected to a gas introduction pipe 327 that goes through the circumferential wall (see FIG. 2) of the chamber body 12. With this, the reaction gas nozzle 321 is supported. The reaction gas (e.g., BTBAS gas) is supplied to the reaction gas nozzle 321 through the gas introduction pipe 327, and then supplied toward the turntable 2 through the reaction gas flow passage 326 from the plural ejection holes 323. In addition, the reaction gas injector 3B is arranged so that the reaction gas flow passage 326 is located upstream relative to the rotation direction of the turntable 2 in relation to the reaction gas nozzle 321.

The reaction gas injector 3B so configured can be arranged so that the lower end surface of the reaction gas nozzle 321 is at the height h3 from the upper surface of the turntable 2. Therefore, the N₂ gas from the separation areas D1, D2 is more likely to flow over the reaction gas injector 3B and less likely to flow into the process area (P1 or P2) below the reaction gas injector 3B. In addition, the lower surface of the reaction gas nozzle 321 is located downstream relative to the rotation direction of the turntable 2 in relation to the reaction gas flow passage 326 through which the reaction gas is supplied toward the turntable 2. Therefore, the reaction gas from the reaction gas flow passage 326 can remain in the space between the lower surface of the reaction gas nozzle 321 and the turntable 2, which increases an adsorption rate of the BTBAS gas onto the wafer W. Moreover, the reaction gas flowing out from the ejection holes 323 hits the guide plate 325 and thus spreads as shown in Section (b) of FIG. 30. Therefore, the concentration of the reaction gas can be uniform along the longitudinal direction of the gas flow passage 326.

Incidentally, the reaction gas injector 3B may be arranged so that the gas flow passage 326 is located downstream relative to the rotation direction of the turntable 2 in relation to the reaction gas nozzle 321. In this case, the lower surface of the reaction gas nozzle 321 is located upstream relative to the rotation direction, leaving a narrow gap substantially equal to the height h3 (FIG. 12) with respect to the turntable 2. Therefore, the reaction gas injector 3B according to such arrangement can impede the separation gas from flowing into the space below the reaction gas injector 3B, thereby avoiding the dilution of the reaction gas from the reaction gas injector 3B.

Incidentally, the nozzle cover 34 shown in FIG. 11, the flow regulatory plates 37A, 37B shown in FIG. 28, and the reaction gas injectors 3A, 3B shown in FIGS. 29 and 30 may be provided in the first area 48A in order to supply the BTBAS gas toward the turntable 2 and/or in the second area 48B in order to supply the O₃ gas toward the turntable 2.

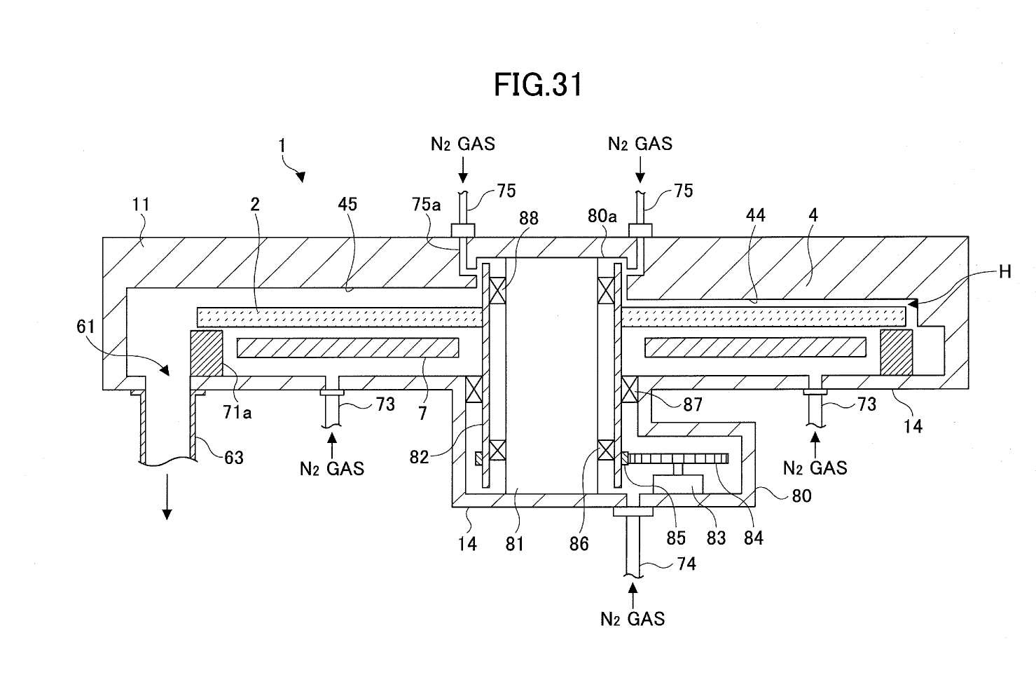

Another embodiment according to the present invention is explained in the following. Referring to FIG. 31, the bottom portion 14 of the chamber body 12 has a center opening and a housing case 80 is attached to the bottom portion 14 in an air-tight manner. In addition, the ceiling plate 11 has a center concave portion 80a. A pillar 81 is placed on the bottom surface of the housing case 80, and a top end portion of the pillar 81 reaches a bottom surface of the center concave portion 80a. The pillar 81 can impede the first reaction gas (BTBAS) ejected from the first reaction gas nozzle 31 and the second reaction gas (O₃) ejected from the second reaction gas nozzle 32 from being intermixed through the center portion of the vacuum chamber 1.

In addition, a rotation sleeve 82 is provided in order to coaxially surround the pillar 81. The rotation sleeve 82 is supported by bearings 86, 88 attached on the outer surface of the pillar 81 and a bearing 87 attached on the inner circumferential surface of the housing case 80. Additionally, a gear 85 is attached on the rotation sleeve 82. Moreover, a ring-shaped turntable 2 is attached at the inner circumferential surface on the outer circumferential surface of the rotation sleeve 82. A driving portion 83 is housed in the housing case 80, and a gear 84 is attached to a shaft extending from the driving portion 83. The gear 84 is meshed with the gear 85, so that the rotation sleeve 82 and thus the turntable 2 can be rotated by the driving portion 83.

A purge gas supplying pipe 74 is connected to the bottom of the housing case 80, so that a purge gas is supplied into the housing case 80. With this, the inside space of the housing case 80 can be maintained at higher pressures than the inner space of the vacuum chamber 1 in order to impede the reaction gas from flowing into the housing case 80. Therefore, no film deposition takes place in the housing case 80 and thus maintenance frequency can be reduced. In addition, purge gas supplying pipes 75 are connected to corresponding conduits 75a reaching from the upper outside surface of the vacuum chamber 1 to the inner wall of the concave portion 80a, and thus purge gas is supplied to the upper end portion of the rotation sleeve 82. With this purge gas, the space defined by the inner surface of the concave portion 80a and the outer circumferential surface of the rotation sleeve 82 can be maintained at higher pressures than the inner space of the vacuum chamber 1, thereby impeding the BTBAS gas and the O₃ gas from being intermixed through the space. While two purge gas supplying pipes 75 and the two conduits 75a are illustrated, the number of the purge gas supplying pipes 75 and the number of the conduits 75a may be determined so that the intermixture of the BTBAS gas and the O₃ gas is surely avoided through the space between the inner wall of the concave portion 80a and the outer circumferential wall of the turntable 2.

Even in these configurations, the convex portions 4 (lower ceiling surfaces 44) are provided in the corresponding separation areas, so that the spaces, which correspond to the spaces H shown in, for example, FIG. 4, between the turntable 2 and the lower ceiling surface 44 can be maintained at higher pressures than the first area where the BTBAS gas is supplied and the second area where the O₃ gas is supplied. In addition, the space between the inner circumferential surface of the concave portion 80a and the rotation sleeve 82 can be maintained at higher pressure than the first and the second areas by the N₂ gas serving as the separation gas from the purge gas supplying pipe 75. Namely, the center separation area can be created in this embodiment. Moreover, the spaces (H) in the corresponding separation areas are in pressure communication with each other through the space between the inner circumferential surface of the concave portion 80a and the rotation sleeve 82. Therefore, the separation space can be created in this embodiment. Accordingly, the same effects or advantages can be provided by this embodiment.

Incidentally, while a protrusion portion (corresponding to the protrusion portion 5 in FIGS. 1, 2 and the like) is omitted in FIG. 31, the protrusion portion is formed integrally with the convex portion 4. The protrusion portion may be formed separately from the convex portion 4 even in this embodiment. In addition, the height of the protrusion portion may be less than that of the convex portion 4 from the turntable 2. In addition, the bent portion 46 shown in FIG. 5 and the inner circumferential surface 46a shown in FIG. 14 may be provided in the film deposition apparatus shown in FIG. 31. Moreover, the baffle plate 60B may be provided in the film deposition apparatus shown in FIG. 31. Furthermore, the reaction gas nozzles 31, 32 may be provided with the nozzle cover 34 (FIG. 11) or the flow regulatory plates 37A, 37B (FIG. 28) in the film deposition apparatus according to this embodiment. In addition, the reaction gas injector 3A (FIG. 29) or 3B (FIG. 30) may be used instead of the reaction gas nozzles 31, 32 in the film deposition apparatus according to this embodiment. Moreover, the showerheads explained above and modified examples of the convex portions 4 may be applied to the film deposition apparatus according to this embodiment.

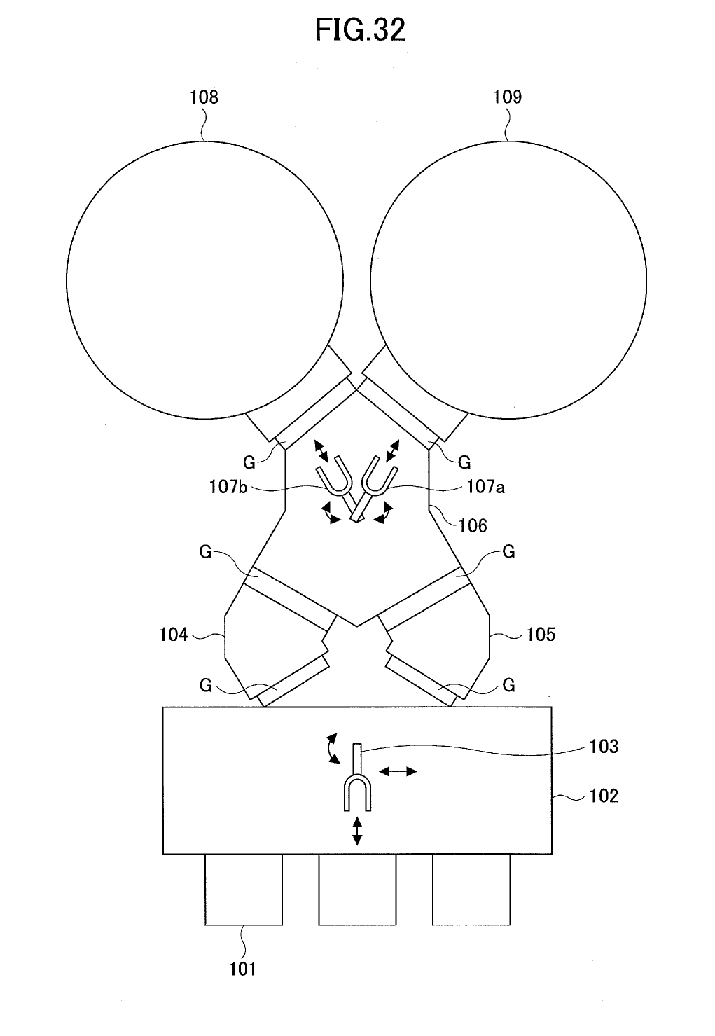

The film deposition apparatuses according to embodiments of the present invention (including the modifications) may be integrated into a wafer process apparatus, an example of which is schematically illustrated in FIG. 32. The wafer process apparatus includes an atmospheric transfer chamber 102 in which a transfer arm 103 is provided, load lock chambers (preparation chambers) 104, 105 whose atmospheres are changeable between vacuum and atmospheric pressure, a vacuum transfer chamber 106 in which two transfer arms 107a, 107b are provided, and film deposition apparatuses 108, 109 according to embodiments of the present invention. The load lock chambers 104, 105 and the film deposition apparatuses 108, 109 are coupled with the vacuum transfer chamber 106 via gate valves G, and the load lock chambers 104, 105 are coupled with the atmospheric transfer chamber 102 via gate valves G. In addition, the wafer process apparatus includes cassette stages (not shown) on which a wafer cassette 101 such as a Front Opening Unified Pod (FOUP) is placed. The wafer cassette 101 is brought onto one of the cassette stages, and connected to a transfer in/out port provided between the cassette stage and the atmospheric transfer chamber 102. Then, a lid of the wafer cassette (FOUP) 101 is opened by an opening/closing mechanism (not shown) and the wafer is taken out from the wafer cassette 101 by the transfer arm 103. Next, the wafer is transferred to the load lock chamber 104 (or 105). After the load lock chamber 104 (or 105) is evacuated, the wafer in the load lock chamber 104 (or 105) is transferred further to one of the film deposition apparatuses 108, 109 through the vacuum transfer chamber 106 by the transfer arm 107a (or 107b). In the film deposition apparatus 108 (or 109), a film is deposited on the wafer in such a manner as described above. Because the wafer process apparatus has two film deposition apparatuses 108, 109, each of which can house five wafers at a time, the ALD (or MLD) mode deposition can be performed at high throughput.

The film deposition apparatus according to embodiments of the present invention may be used to deposit silicon nitride in addition to silicon oxide. Moreover, the film deposition apparatus according to embodiments of the present invention is used for ALDs of aluminum oxide (AL₂O₃) using trymethylaluminum (TMA) and O₃ gas, zirconium oxide (ZrO₂) using tetrakis(ethylmethylamino)zirconium (TEMAZ) and O₃ gas, hafnium dioxide (HfO₂) using tetrakis(ethylmethylamino)hafnium (TEMAH) and O₃ gas, strontium oxide (SrO) using bis(tetra methyl heptandionate) strontium (Sr(THD)₂) and O₃ gas, titanium oxide (TiO₂) using (methyl-pentadionate) (bis-tetra-methyl-heptandionate) titanium (Ti(MPD) (THD)₂) and O₃ gas, or the like. In addition, oxide plasma may be used instead of O₃ gas. Even when these reaction gases are used, the above advantages and effects are provided.

Although the present invention has been described in conjunction with the foregoing specific embodiment, many alternatives, variations and modifications within the scope of the appended claims will be apparent to those of ordinary skill in the art.

What is claimed is:

1. A film deposition apparatus for depositing a film on a substrate by performing plural cycles of alternately supplying at least two kinds of reaction gases that react with each other on the substrate to produce a layer of a reaction product in a chamber, the film deposition apparatus comprising:
a turntable that is rotatably provided in a chamber and includes a substrate receiving area in which a substrate is placed, wherein said turntable has an upper surface, a lower surface, and a side surface that is positioned between the upper surface of the turntable and the lower surface of the turntable, and wherein said chamber has an upper surface, a lower surface, and a side surface that is positioned between the upper surface of the chamber and the lower surface of the chamber;
a separation member that extends to cover a rotation center of the turntable and two different points on a circumference of the turntable above the turntable, thereby separating the inside of the chamber into a first area and a second area, wherein a pressure in a space between the turntable and the separation member may be maintained higher than pressures of the first area and the second area by use of a first separation gas supplied to the space, said separation member having a bent portion that substantially fills in a gap between the side surface of the turntable and the side surface of the chamber;
a pressure control portion that maintains along with the separation member the pressure in the space between the turntable and the separation member higher than the pressures in the first area and the second area;
a first reaction gas supplying portion that is provided in the first area and supplies a first reaction gas toward the turntable;
a second reaction gas supplying portion that is provided in the second area and supplies a second reaction gas toward the turntable;
a first evacuation port that evacuates therefrom the first reaction gas supplied in the first area and the first separation gas supplied to the space between the separation member and the turntable by way of the first area, after the first reaction gas and the first separation gas converge with each other in the first area; and
a second evacuation port that evacuates therefrom the second reaction gas supplied in the second area and the first separation gas supplied to the space between the separation member and the turntable by way of the second area, after the second reaction gas and the first separation gas converge with each other in the second area.

2. The film deposition apparatus of claim 1, wherein the pressure control portion includes an inner circumferential surface of the chamber being arranged closer to the turntable below the separation member than in the first area and the second area.

3. The film deposition apparatus of claim 1, wherein the pressure control portion includes a plate member arranged between the turntable and the inner circumferential surface of the chamber, thereby impeding the first separation gas from flowing around toward a space below the turntable.

4. The film deposition apparatus of claim 3, wherein the plate member includes a third evacuation port having an inner diameter smaller than inner diameters of the first evacuation port and the second evacuation port, and wherein the film deposition apparatus further comprises a groove that allows the first, the second, and the third evacuation ports to be in pressure communication with one another below the plate member.

5. The film deposition apparatus of claim 1, wherein the pressure control portion includes a second separation gas supplying portion that supplies a second separation gas toward the space between the turntable and the separation member in a direction from the circumference of the turntable to the center of the turntable.

6. The film deposition apparatus of claim 5, wherein the second separation gas supplying portion includes a pipe introduced from the circumferential wall of the chamber.

7. The film deposition apparatus of claim 1, wherein the separation member is arranged so that a volume of the space between the turntable and the separation member is smaller than a volume of the first area and a volume of the second area.

8. The film deposition apparatus of claim 1, wherein plural holes that supply the first separation gas are formed in a lower surface of the separation member.

9. The film deposition apparatus of claim 1, further comprising a first separation gas supplying portion that supplies the first separation gas to the space between the turntable and the separation member.

10. The film deposition apparatus of claim 9, wherein the first separation gas supplying portion is introduced from one of a circumferential wall of the chamber and a ceiling portion of the chamber, or the combination of the circumferential wall and the ceiling portion of the chamber.

11. The film deposition apparatus of claim 1, wherein at least one of the first reaction gas supplying portion and the second reaction gas supplying portion is away from a ceiling surface in the corresponding one of the first area and the second area.

12. The film deposition apparatus of claim 1, wherein at least one of the first reaction gas supplying portion and the second reaction gas supplying portion is provided with a flow regulatory member that promotes the first separation gas flowing through a space between a ceiling of the chamber and the reaction gas nozzle provided with the flow regulatory member.

13. The film deposition apparatus of claim 1, wherein the pressure control portion supplies the first separation gas so that a first pressure in a first region of the space between the turntable and the separation member is greater than a second pressure in a second region of the space between the turntable and the separation member, the second region being located on the side of the center of the turntable in relation to the first region.

14. The film deposition apparatus of claim 13, wherein the pressure control portion includes a first plate member including plural first ejection holes in the first region, and a second plate member including plural second ejection holes in the second region.

15. The film deposition apparatus of claim 14, wherein a density of the plural first ejection holes in the first plate member is greater than a density of the plural second ejection holes in the second plate member.

16. The film deposition apparatus of claim 14, further comprising a first supplying pipe that supplies the first separation gas to the first plate member, and a second supplying pipe that supplies the first separation gas to the second plate member.

17. The film deposition apparatus of claim 16, wherein the first supplying pipe supplies the first separation gas from one of a ceiling portion of the chamber and the circumferential wall of the chamber, and
wherein the second supplying pipe supplies the first separation gas from one of a ceiling portion of the chamber and the circumferential wall of the chamber.

18. The film deposition apparatus of claim 13, wherein the pressure control portion includes a third supplying portion that extends in a first direction transverse to a rotation direction of the turntable and has plural third ejection holes that are arranged along the first direction, wherein the opening density of the plural third ejection holes is greater in the first region than in the second region.

19. The film deposition apparatus of claim 13, wherein the pressure control portion includes
a third supplying portion that extends in the first region and the second region along a first direction transverse to a rotation direction of the turntable and has plural third ejection holes that are arranged along the first direction; and
a fourth supplying portion that extends in the first region along the first direction, and has plural fourth ejection holes that are arranged along the first direction.

20. A film deposition method for depositing a film on a substrate by carrying out plural cycles of alternately supplying at least two kinds of reaction gases that react with each other on the substrate to produce a layer of a reaction product in a chamber, the film deposition method comprising steps of:
placing a substrate in a substrate receiving area of a turntable that is rotatably provided in the chamber, wherein said turntable has an upper surface, a lower surface, and a side surface that is positioned between the upper surface of the turntable and the lower surface of the turntable, and wherein said chamber has an upper surface, a lower surface, and a side surface that is positioned between the upper surface of the chamber and the lower surface of the chamber;
supplying a first separation gas to a space between the turntable and a separation member that extends to cover a rotation center of the turntable and two different points on a circumference of the turntable above the turntable, thereby separating the inside of the chamber into a first area and a second area, so that a pressure in the space is greater than pressures of the first area and the second area; said separation member having a bent portion that substantially fills in a gap between the side surface of the turntable and the side surface of the chamber;
supplying a first reaction gas from a first gas supplying portion arranged in the first area toward the turntable;
supplying a second reaction gas from a second gas supplying portion arranged in the second area toward the turntable;
evacuating the first reaction gas supplied to the first area and the first separation gas from the space between the turntable and the separation member by way of the first area, after the first reaction gas and the first separation gas converge in the first area; and
evacuating the second reaction gas supplied to the second area and the first separation gas from the space between the turntable and the separation member by way of the second area, after the second reaction gas and the first separation gas converge in the second area.

21. The film deposition method of claim 20, wherein the first reaction gas and the second reaction gas are supplied continuously during deposition.

22. The film deposition method of claim 21, wherein the first separation gas is supplied from a first separation gas supplying portion introduced from one of a circumferential wall of the chamber and a ceiling portion of the chamber, or the combination of the circumferential wall and the ceiling portion of the chamber.
